(19) United States
(12) Patent Application Publication
(10) Pub. No.: US 2025/0048767 A1
(43) Pub. Date: Feb. 6, 2025

(54) LIGHT RECEIVING DEVICE AND ELECTRONIC DEVICE

(71) Applicant: SONY SEMICONDUCTOR SOLUTIONS CORPORATION, KANAGAWA (JP)

(72) Inventor: TOMOHIKO BABA, KANAGAWA (JP)

(21) Appl. No.: 18/716,950

(22) PCT Filed: Oct. 21, 2022
(86) PCT No.: PCT/JP2022/039211

§ 371 Date: Jun. 6, 2024

(30) Foreign Application Priority Data
Dec. 14, 2021 (JP) 2021-202651

(51) Int. Cl. H01L 27/146; G06V 40/13

(52) U.S. Cl. CPC H01L 27/14627; G06V 40/1318; H01L 27/14623; H01L 27/14685

(57) ABSTRACT

A light receiving device and an electronic device capable of achieving a preferable structure in a case where a pinhole is arranged between a photodetector and a microlens are provided. A light receiving device of the present disclosure includes a substrate including a photodetector, an optical system provided above the photodetector, and a first light shielding layer provided between the photodetector and the optical system and having a first opening, in which the optical system includes a microlens having a shape concave toward a side of a subject.

### TECHNICAL FIELD

The present disclosure relates to a light receiving device and an electronic device.

### BACKGROUND ART

A solid-state imaging device including a photodetector and a microlens for each individual pixel is known. In this case, one or more pinholes may be arranged between the photodetector and the microlens of each pixel. Thus, it is possible to suppress excessive light from entering the photodetector and to improve the resolution of the solid-state imaging device.

### CITATION LIST

### Patent Document

Patent Document 1: Japanese Patent No. 5488928
Patent Document 2: Japanese Patent Application Laid-Open No. 2007-520743
Patent Document 3: Japanese Translation of PCT International Application Publication No. 2010-539562

### SUMMARY OF THE INVENTION

### Problems to be Solved by the Invention

However, when the pinholes are arranged as described above, light is restricted from entering the photodetector from multiple directions, which causes a problem that utilization efficiency of light is lowered. Furthermore, a spot of light is distorted, causing a problem that image quality of the solid-state imaging device is deteriorated.

Therefore, the present disclosure provides a light receiving device and an electronic device capable of achieving a preferable structure in a case where a pinhole is arranged between a photodetector and a microlens.

### Solutions to Problems

A light receiving device according to a first aspect of the present disclosure includes a substrate including a photodetector, an optical system provided above the photodetector, and a first light shielding layer provided between the photodetector and the optical system and having a first opening, in which the optical system includes a microlens having a shape concave toward a side of a subject. Thus, for example, it is possible to achieve a preferable structure in a case where a pinhole (first opening) is arranged between the photodetector and the microlens, such as increasing an NA (numerical aperture) of the optical system or correcting aberration of image formation.

Furthermore, in the first aspect, the optical system may further include a microlens having a shape convex toward the side of the subject. Thus, for example, a combination of a concave shape and a convex shape makes it possible to bring the image formation closer to no aberration.

Furthermore, in the first aspect, the optical system may include, as the microlens, a first lens having a shape convex toward the side of the subject, a second lens provided above the first lens and having a shape convex toward the side of the subject, and a third lens provided above the second lens and having a shape concave toward the side of the subject. Thus, for example, it is possible to preferably collect the light incident on the optical system while bringing the image formation closer to no aberration.

Furthermore, in the first aspect, an optical axis of the second lens may be on a first direction side with respect to an optical axis of the first lens, and an optical axis of the third lens may be on a side opposite to the first direction with respect to an optical axis of the first lens. Thus, for example, aberration correction capability of the optical system can be improved.

Furthermore, in the first aspect, the first opening may be provided at a position not overlapping with an optical axis of the first lens. Thus, for example, it is possible to achieve a structure in which the first light shielding layer easily shields excess light, and further, it is possible to provide an angle of view to the pixel including the first opening.

Furthermore, the light receiving device of the first aspect may further include a first transparent layer provided between the substrate and the first light shielding layer. Thus, for example, light can be propagated between the substrate and the first light shielding layer.

Furthermore, the light receiving device of the first aspect may further include a second light shielding layer provided between the photodetector and the first light shielding layer and having a second opening. Thus, for example, the angular resolution can be improved by the presence of the plurality of pinholes (first and second openings).

Furthermore, in the first aspect, the second opening may be provided at a position not overlapping with the first opening in plan view. Thus, for example, it is possible to achieve a structure in which the first and second light shielding layers can easily shield excessive light.

Furthermore, the light receiving device of the first aspect may further include a second transparent layer provided between the substrate and the second light shielding layer. Thus, for example, light can be propagated between the substrate and the second light shielding layer.

Furthermore, the light receiving device of the first aspect may include, as the photodetector and the optical system, a plurality of photodetectors provided in the substrate, and a plurality of optical systems provided above the plurality of photodetectors. Thus, for example, an array of photodetectors and an array of microlenses can be achieved, and a structure suitable for an imaging device or the like can be achieved.

Furthermore, the light receiving device of the first aspect may further include a common lens provided above the plurality of optical systems. Thus, for example, the angle of view of the light receiving device can be increased.

Furthermore, in the first aspect, one of an upper surface and a lower surface of the common lens may have a convex or concave shape toward the side of the subject. Thus, for example, the angle of view of the light receiving device can be increased by an operation of the convex lens or the concave lens.

Furthermore, in the first aspect, another of the upper surface and the lower surface of the common lens may be a flat surface. Thus, for example, it is possible to achieve a structure in which the common lens is easily arranged on the array of microlenses.

Furthermore, in the first aspect, another of the upper surface and the lower surface of the common lens may also have a convex or concave shape toward the side of the subject. Thus, for example, the angle of view of the light receiving device can be further increased by an operation of the convex lens or the concave lens.

Furthermore, in the first aspect, the common lens may function as a Fresnel lens or a hologram element. Thus, for example, the common lens can be easily manufactured.

Furthermore, the light receiving device of the first aspect may further include a transparent member provided above the optical system. Thus, for example, a structure suitable for an authentication device or the like can be achieved.

Furthermore, in the first aspect, at least one of an angle θ between an upper light beam and a lower light beam in the optical system, a focal length f of the optical system, or a diameter d of the first opening may have a value satisfying −10°≤θ≤10°, 0.0003 mm<f<3 mm, or 0.02 μm<d<3 μm. Thus, for example, a structure that satisfies an appropriate condition can be achieved.

An electronic device according to a second aspect of the present disclosure includes a substrate including a photodetector, an optical system provided above the photodetector, and a first light shielding layer provided between the photodetector and the optical system and having a first opening, in which the optical system includes a microlens having a shape concave toward a side of a subject. Thus, for example, it is possible to achieve a preferable structure in a case where a pinhole (first opening) is arranged between the photodetector and the microlens, such as increasing an NA (numerical aperture) of the optical system or correcting aberration of image formation.

Furthermore, in the second aspect, the electronic device may function as an imaging device that images the subject. Thus, for example, it is possible to achieve an imaging device with aberration corrected.

Furthermore, in the second aspect, the electronic device may further function as an authentication device that authenticates the subject using an image obtained by imaging the subject. Thus, for example, it is possible to achieve an authentication device with improved authentication accuracy by correcting aberration.

### BRIEF DESCRIPTION OF DRAWINGS

FIG. 1 is a block diagram illustrating a configuration of a solid-state imaging device of a first embodiment.

FIG. 2 is a cross-sectional view illustrating a structure of the solid-state imaging device of the first embodiment.

FIG. 3 is a plan view illustrating the structure of the solid-state imaging device of the first embodiment.

FIG. 4 is a cross-sectional view for describing a function of the solid-state imaging device of the first embodiment.

FIG. 5 is a cross-sectional view for describing a function of a solid-state imaging device of a comparative example of the first embodiment.

FIG. 6 is a cross-sectional view for describing a function of the solid-state imaging device of the first embodiment.

FIG. 7 is a cross-sectional view illustrating a structure of a solid-state imaging device of a second embodiment.

FIG. 8 is a cross-sectional view for describing a function of the solid-state imaging device of the second embodiment.

FIG. 9 is a cross-sectional view illustrating a structure of a solid-state imaging device of a third embodiment.

FIG. 10 is a cross-sectional view for describing a function of the solid-state imaging device of the third embodiment.

FIG. 11 is a cross-sectional view and a plan view for describing details of the solid-state imaging device of the third embodiment.

FIG. 12 is a cross-sectional view illustrating a structure of a solid-state imaging device of a fourth embodiment.

FIG. 13 is a cross-sectional view for describing a function of the solid-state imaging device of the fourth embodiment.

FIG. 14 is a schematic diagram illustrating a configuration of a solid-state imaging device of a fifth embodiment.

FIG. 15 is a schematic diagram illustrating a configuration of a solid-state imaging device of a sixth embodiment.

FIG. 16 is a cross-sectional view illustrating a structure of a solid-state imaging device of a seventh embodiment.

FIG. 17 is a cross-sectional view (1/12) illustrating a method of manufacturing the solid-state imaging device of the seventh embodiment.

FIG. 18 is a cross-sectional view (2/12) illustrating the method of manufacturing the solid-state imaging device of the seventh embodiment.

FIG. 19 is a cross-sectional view (3/12) illustrating the method of manufacturing the solid-state imaging device of the seventh embodiment.

FIG. 20 is a cross-sectional view (4/12) illustrating the method of manufacturing the solid-state imaging device of the seventh embodiment.

FIG. 21 is a cross-sectional view (5/12) illustrating the method of manufacturing the solid-state imaging device of the seventh embodiment.

FIG. 22 is a cross-sectional view (6/12) illustrating the method of manufacturing the solid-state imaging device of the seventh embodiment.

FIG. 23 is a cross-sectional view (7/12) illustrating the method of manufacturing the solid-state imaging device of the seventh embodiment.

FIG. 24 is a cross-sectional view (8/12) illustrating the method of manufacturing the solid-state imaging device of the seventh embodiment.

FIG. 25 is a cross-sectional view (9/12) illustrating the method of manufacturing the solid-state imaging device of the seventh embodiment.

FIG. 26 is a cross-sectional view (10/12) illustrating the method of manufacturing the solid-state imaging device of the seventh embodiment.

FIG. 27 is a cross-sectional view (11/12) illustrating the method of manufacturing the solid-state imaging device of the seventh embodiment.

FIG. 28 is a cross-sectional view (12/12) illustrating the method of manufacturing the solid-state imaging device of the seventh embodiment.

FIG. 29 is a cross-sectional view illustrating details of the method of manufacturing the solid-state imaging device of the seventh embodiment.

FIG. 30 is a block diagram illustrating a configuration example of an electronic device.

FIG. 31 is a block diagram illustrating a configuration example of a mobile body control system.

FIG. 32 is a plan view illustrating a specific example of a setting position of the imaging unit in FIG. 31.

FIG. 33 is a diagram illustrating an example of a schematic configuration of an endoscopic surgery system.

FIG. 34 is a block diagram illustrating an example of a functional configuration of a camera head and a CCU.

### MODE FOR CARRYING OUT THE INVENTION

Hereinafter, embodiments of the present disclosure will be described with reference to the drawings.

### First Embodiment

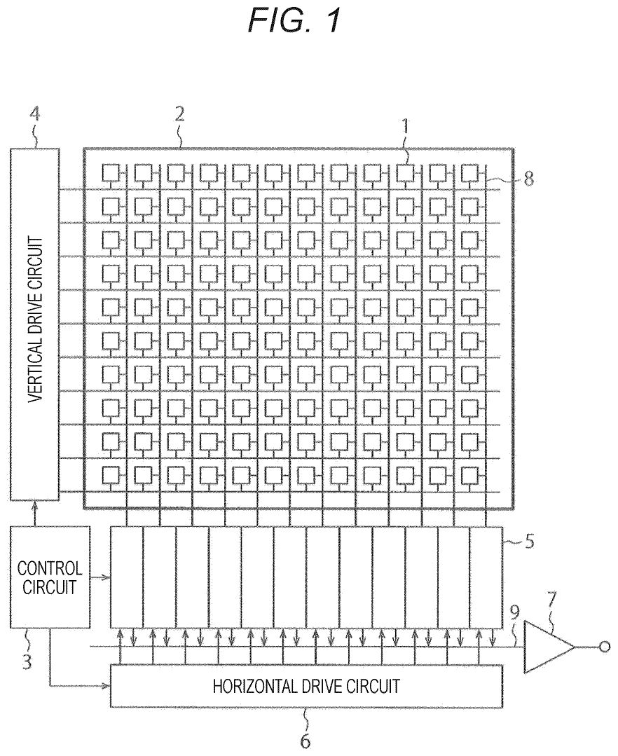

FIG. 1 is a block diagram illustrating a configuration of a solid-state imaging device of a first embodiment.

The solid-state imaging device in FIG. 1 includes a pixel array region 2 including a plurality of pixels 1, a control circuit 3, a vertical drive circuit 4, a plurality of column signal processing circuits 5, a horizontal drive circuit 6, an output circuit 7, a plurality of vertical signal lines 8, and a horizontal signal line 9. The solid-state imaging device in FIG. 1 is an example of a light receiving device of the present disclosure. The solid-state imaging device in FIG. 1 is, for example, a complementary metal oxide semiconductor (CMOS) image sensor.

Each pixel 1 includes a photodetector for detecting light. For example, in a case where the solid-state imaging device in FIG. 1 is a CMOS image sensor, each pixel 1 includes a photodiode that is a photoelectric conversion unit as a photodetector, and further includes a MOS transistor as a pixel transistor. Examples of the pixel transistor include a transfer transistor, a reset transistor, an amplification transistor, a selection transistor, and the like. These pixel transistors may be shared by several pixels 1.

The pixel array region 2 includes a plurality of pixels 1 arranged in a two-dimensional array. The pixel array region 2 includes, for example, an effective pixel region that receives light, performs photoelectric conversion, and outputs a signal charge generated by the photoelectric conversion, and a black reference pixel region that outputs optical black serving as a reference of a black level. In general, the black reference pixel region is arranged on an outer peripheral portion of the effective pixel region.

The control circuit 3 generates various signals serving as references of operations of the vertical drive circuit 4, the column signal processing circuit 5, the horizontal drive circuit 6, and the like on the basis of a vertical synchronization signal, a horizontal synchronization signal, a master clock, and the like. The signals generated by the control circuit 3 are, for example, a clock signal and a control signal, and are input to the vertical drive circuit 4, the column signal processing circuit 5, the horizontal drive circuit 6, and the like.

The vertical drive circuit 4 includes, for example, a shift register, and scans each of the pixels 1 in the pixel array region 2 in the vertical direction row by row. For example, the vertical drive circuit 4 supplies a pixel signal based on the signal charge generated by each pixel 1 to the column signal processing circuit 5 through the vertical signal line 8.

The column signal processing circuit 5 is arranged, for example, for every column of the pixels 1 in the pixel array region 2, and performs signal processing of the signals output from the pixels 1 of one row for every column on the basis of a signal from the black reference pixel region. Examples of this signal processing are noise removal and signal amplification. The horizontal drive circuit 6 includes, for example, a shift register, and supplies the pixel signal from each of the column signal processing circuits 5 to the horizontal signal line 9.

The output circuit 7 performs signal processing on the signal supplied from each of the column signal processing circuits 5 through the horizontal signal line 9, and outputs the signal subjected to the signal processing.

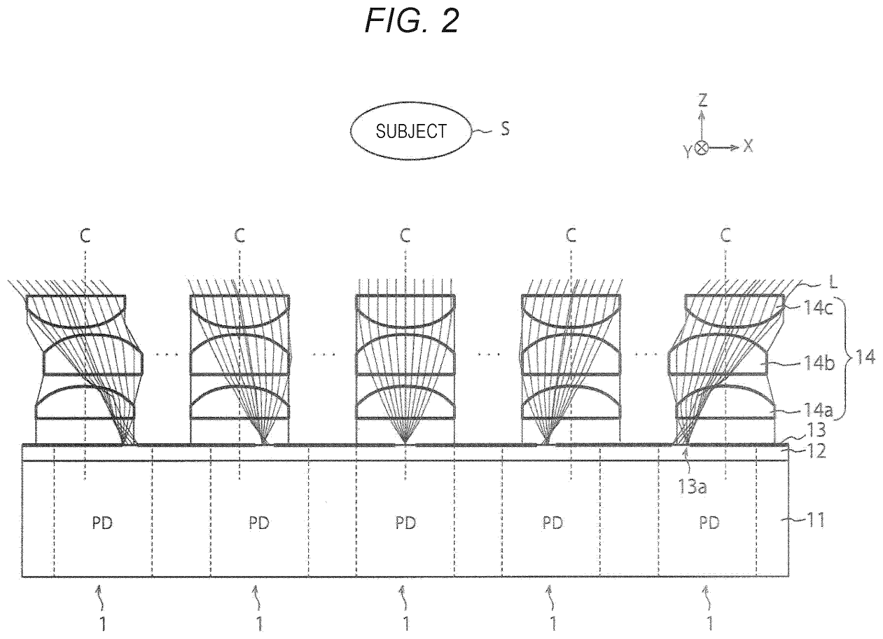

FIG. 2 is a cross-sectional view illustrating a structure of the solid-state imaging device of the first embodiment. FIG. 2 schematically illustrates a cross section of five pixels 1 (pixel cells) in the pixel array region 2 illustrated in FIG. 1.

FIG. 2 illustrates an X axis, a Y axis, and a Z axis perpendicular to each other. The X direction and the Y direction correspond to a lateral direction (horizontal direction), and the Z direction corresponds to a longitudinal direction (vertical direction). Furthermore, a +Z direction corresponds to an upward direction, and a −Z direction corresponds to a downward direction. Note that the −Z direction may strictly match the gravity direction, or does not necessarily strictly match the gravity direction. In FIG. 2, a subject S of the solid-state imaging device is located in the +Z direction of the solid-state imaging device.

As illustrated in FIG. 2, the solid-state imaging device of the present embodiment includes a substrate 11, a transparent layer 12, and a light shielding layer 13. The transparent layer 12 is an example of a first transparent layer of the present disclosure. The light shielding layer 13 is an example of a first light shielding layer of the present disclosure. The substrate 11 includes a photodetector PD for each pixel 1, and the light shielding layer 13 includes a pinhole 13a for each pixel 1. The pinhole 13a is an example of a first opening of the present disclosure.

As illustrated in FIG. 2, the solid-state imaging device of the present embodiment further includes an optical system 14 for each pixel 1. The optical system 14 of each pixel 1 includes three microlenses of a lower lens 14a, an intermediate lens 14b, and an upper lens 14c. The lower lens 14a, the intermediate lens 14b, and the upper lens 14c are examples of a first lens, a second lens, and a third lens of the present disclosure, respectively.

The substrate 11 is, for example, a semiconductor substrate such as a silicon (Si) substrate. FIG. 2 illustrates five photodetectors PD included in five pixels 1. These photodetectors PD function as imaging elements of a solid-state imaging device. Each of the photodetectors PD is, for example, a photodiode formed by a pn junction between a p-type semiconductor region and an n-type semiconductor region in the substrate 11.

The transparent layer 12 is provided on the substrate 11. The transparent layer 12 is formed by a material capable of transmitting light. The transparent layer 12 is, for example, a SiO₂ film (silicon oxide film).

The light shielding layer 13 is provided on the transparent layer 12. The light shielding layer 13 is formed by a material capable of blocking light. The light shielding layer 13 is, for example, a metal layer such as a tungsten (W) layer. FIG. 2 illustrates five pinholes 13a included in five pixels 1. Light incident on the light shielding layer 13 of each pixel 1 passes through the pinhole 13a, passes through the transparent layer 12, and reaches the photodetector PD.

In each pixel 1, the optical system 14 is disposed above the substrate 11 via the transparent layer 12 and the light shielding layer 13. The lower lens 14a is disposed above the pinhole 13a. The intermediate lens 14b is disposed above the lower lens 14a. The upper lens 14c is disposed above the intermediate lens 14b. In FIG. 2, a plurality of light beams L incident on each pixel 1 sequentially passes through the upper lens 14c, the intermediate lens 14b, and the lower lens 14a, and reach the pinhole 13a. Each of the lower lens 14a, the intermediate lens 14b, and the upper lens 14c of the present embodiment is a microlens having positive power, and has approximately the same size as the pixel 1 and the photodetector PD in plan view.

The lower lens 14a has an upper surface protruding toward the subject S (+Z direction) side and a flat lower surface. As a result, the lower lens 14a has a shape convex toward the subject S side. In other words, a convex surface (upper surface) of the lower lens 14a faces the subject S side. FIG. 2 illustrates an optical axis C of the lower lens 14a in each pixel 1.

The intermediate lens 14b also has an upper surface protruding toward the subject S side and a flat lower surface. As a result, the intermediate lens 14b has a shape convex toward the subject S side. In other words, the convex surface (upper surface) of the intermediate lens 14b faces the subject S side.

The upper lens 14c has a lower surface protruding to an opposite side (−Z direction) of the subject S and a flat upper surface. As a result, the upper lens 14b has a shape convex toward the opposite side of the subject S, that is, a shape concave toward the subject S side. In other words, the convex surface (lower surface) of the upper lens 14c faces the opposite side of the subject S, that is, the photodetector PD side.

In the present embodiment, light generated from the subject S and light reflected by the subject S are incident on the optical system 14 of each pixel 1. The light incident on the optical system 14 sequentially passes through the upper lens 14c, the intermediate lens 14b, and the lower lens 14a, and then is blocked by the light shielding layer 13 or passes through the pinhole 13a. The light having passed through the pinhole 13a passes through the transparent layer 12, reaches the photodetector PD, and is detected by the photodetector PD. In this manner, the solid-state imaging device of the present embodiment can image the subject S.

The solid-state imaging device of the present embodiment is provided in, for example, an imaging device that images the subject S or an authentication device that authenticates the subject S using an image obtained by imaging the subject S. This authentication device performs, for example, fingerprint authentication, vein authentication, iris authentication, face authentication, and the like. Furthermore, the solid-state imaging device of the present embodiment may be provided in an electronic device other than the imaging device and the authentication device. Examples of such an electronic device include a line-of-sight recognition device, a lens-less microscope, a cell separation device, a glass inspection device, a semiconductor inspection device, and a contact copying machine.

Note that the solid-state imaging device of the present embodiment may be a charge coupled device (CCD) type image sensor instead of the CMOS type image sensor. Furthermore, the solid-state imaging device of the present embodiment may include an optical member such as an optical filter (for example, a bandpass filter) between the lower lens 14a and the intermediate lens 14b, between the intermediate lens 14b and the upper lens 14c, near the optical system 14, or above the optical system 14. For example, the solid-state imaging device of the present embodiment may include a transparent member such as a glass cover above the optical system 14, and may include the above-described optical member on a surface of the transparent member.

In FIG. 2, the positional relationship among the pinhole 13a, the lower lens 14a, the intermediate lens 14b, and the upper lens 14c in each pixel 1 is different for each pixel 1. Details of this positional relationship will be described later.

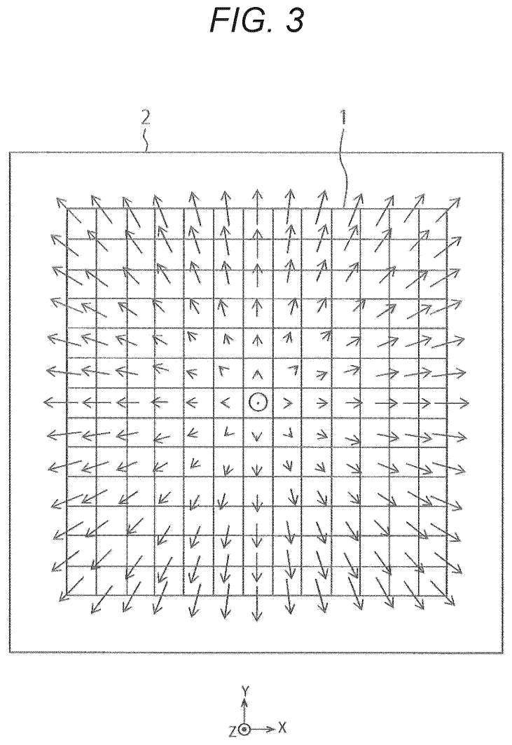

FIG. 3 is a plan view illustrating the structure of the solid-state imaging device of the first embodiment.

FIG. 3 schematically illustrates 169 (13×13) pixels 1 in the pixel array region 2 illustrated in FIG. 1. An arrow illustrated in FIG. 3 indicates an angle of view at which a light beam flies. In the solid-state imaging device of the present embodiment, a light beam of the pixel 1 at a center of the pixel array region 2 flies in parallel in the Z direction, and the light beam of the pixel 1 at a position other than the center of the pixel array region 2 flies in a direction inclined with respect to the Z direction. Specifically, a light beam of the pixel 1 near the center of the pixel array region 2 flies in a direction slightly inclined with respect to the Z direction, and a light beam of the pixel 1 far from the center of the pixel array region 2 flies in a direction greatly inclined with respect to the Z direction. Note that the number of pixels 1 in the pixel array region 2 of the present embodiment may be other than 169.

Next, referring again to FIG. 2, further details of the five pixels 1 illustrated in FIG. 2 will be described.

In FIG. 2, the +Z direction is the subject S side (object side), and the −Z direction is the photodetector PD side (image side). FIG. 2 illustrates five pixels 1 facing directions of angles of view of −41°, −20°, 0°, +20°, and +41°. Specifically, the pixel 1 in the center of FIG. 2 is oriented in a direction with an angle of view of 0°, the two pixels 1 on the right side of FIG. 2 are oriented in directions with angles of view of −20° and −41°, and the two pixels 1 on the left side of FIG. 2 are oriented in directions with angles of view of +20° and +41°.

In FIG. 2, the optical system 14 of the pixel 1 having an angle of view of 0° and ±20° is disposed without eccentricity. Therefore, in the optical system 14 of the pixel 1, the optical axis of the upper lens 14c and the optical axis of the intermediate lens 14b are located on an optical axis C of the lower lens 14a. That is, the optical axes of these three microlenses overlap each other.

On the other hand, optical system 14 of pixel 1 having the angle of view of ±41° is disposed in an eccentric state. For example, in the pixel 1 having the angle of view of +41°, the optical axis of the intermediate lens 14b is located on the +X direction side with respect to the optical axis C of the lower lens 14a, and the optical axis of the upper lens 14c is located on the −X direction side with respect to the optical axis C of the lower lens 14a. That is, the intermediate lens 14b and the upper lens 14c are alternately eccentric with respect to the lower lens 14a. Similarly, in the pixel 1 having the angle of view of −41°, the optical axis of the intermediate lens 14b is located on the −X direction side with respect to the optical axis C of the lower lens 14a, and the optical axis of the upper lens 14c is located on the +X direction side with respect to the optical axis C of the lower lens 14a. One of the +X direction side and the −X direction side is an example on a first direction side of the present disclosure, and the other of the +X direction side and the −X direction side is an example on the opposite side of the first direction of the present disclosure.

In each pixel 1 illustrated in FIG. 2, the position of the pinhole 13a in plan view is shifted to an optimum position with respect to the position of the optical axis C of the lower lens 14a. For example, in the pixel 1 having the angles of view of +20° and +41°, the position of the pinhole 13a in plan view is on the +X direction side with respect to the position of the optical axis C of the lower lens 14a. Similarly, in the pixel 1 having the angles of view of −20° and −41°, the position of the pinhole 13a in plan view is on the −X direction side with respect to the position of the optical axis C of the lower lens 14a. In these four pixels 1, the pinhole 13a is provided at a position not overlapping with the optical axis C of the lower lens 14a. On the other hand, in the pixel 1 having an angle of view of 0°, the pinhole 13a is provided at a position overlapping the optical axis C of the lower lens 14a.

In the present embodiment, a thickness from the upper surface of the upper lens 14c to an upper surface of the light shielding layer 13 is approximately 9 μm, a thickness of the transparent layer 12 is approximately 1 μm, and a thickness of the substrate 11 is approximately 3 μm. Furthermore, the diameter of the pinhole 13a of the present embodiment is approximately 0.24 μm.

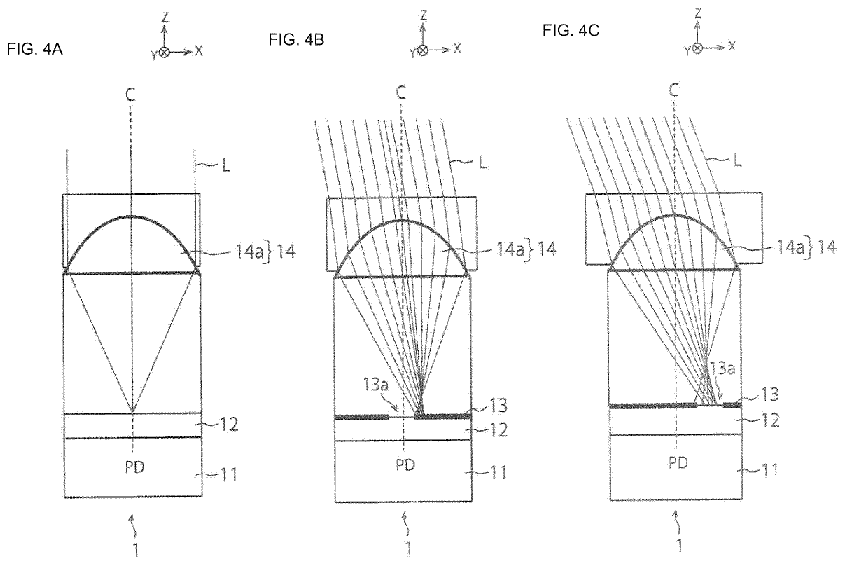

FIG. 4 is a cross-sectional view for describing a function of the solid-state imaging device of the first embodiment.

A of FIG. 4 is a cross-sectional view for describing an operation of the lower lens 14a of each pixel 1. In A of FIG. 4, the parallel light incident on the upper surface of the lower lens 14a is condensed by the lower lens 14a and propagates toward the photodetector PD. The photodetector PD is disposed near a position where the plurality of light beams L illustrated in A of FIG. 4 intersects.

B of FIG. 4 is a cross-sectional view for describing an operation of the pinhole 13a. In B of FIG. 4, parallel light is incident on the upper surface of the lower lens 14a from a direction inclined by 10° with respect to the Z direction. In B of FIG. 4, the parallel light is represented by 12 light beams L. The parallel light is condensed by the lower lens 14a and is incident on the light shielding layer 13. In B of FIG. 4, a position of a principal ray in plan view is shifted by 0.93 μm in the +X direction between the upper surface of the lower lens 14a and the upper surface of the light shielding layer 13. Therefore, in a case where the pinhole 13a having a diameter of 1.00 μm is provided on the optical axis C of the lower lens 14a, almost all of the light beams L illustrated in B of FIG. 4 can be kicked (blocked) by the light shielding layer 13. As described above, the light shielding layer 13 having the pinhole 13a on the optical axis C of the lower lens 14a can kick the light beam L incident on the lower lens 14a while being inclined with respect to the Z direction, and only the light beam L incident on the lower lens 14a while being substantially not inclined with respect to the Z direction can pass through the pinhole 13a.

C of FIG. 4 is also a cross-sectional view for describing the operation of the pinhole 13a. Also, in C of FIG. 4, parallel light is incident on the upper surface of the lower lens 14a from a direction inclined by approximately 10° with respect to the Z direction. However, in C of FIG. 4, the pinhole 13a having a diameter of 1.00 μm is provided at a position shifted by 0.93 μm in the +X direction from the optical axis C of the lower lens 14a. Therefore, almost all of the light beam L illustrated in C of FIG. 4 can pass through the pinhole 13a without being kicked by the light shielding layer 13.

By applying this phenomenon, the angle of view can be provided to each pixel 1. For example, as in the solid-state imaging device illustrated in FIG. 2, it is conceivable that the pinhole 13a of the pixel 1 at the center of the pixel array region 2 is arranged on the optical axis C, and the pinholes 13a of the other pixels 1 are arranged so as to be shifted from the optical axis C as the distance from the center of the pixel array region 2 increases. Thus, the angle of view can be gradually given to these pixels 1, and a function like a camera can be achieved easily and inexpensively.

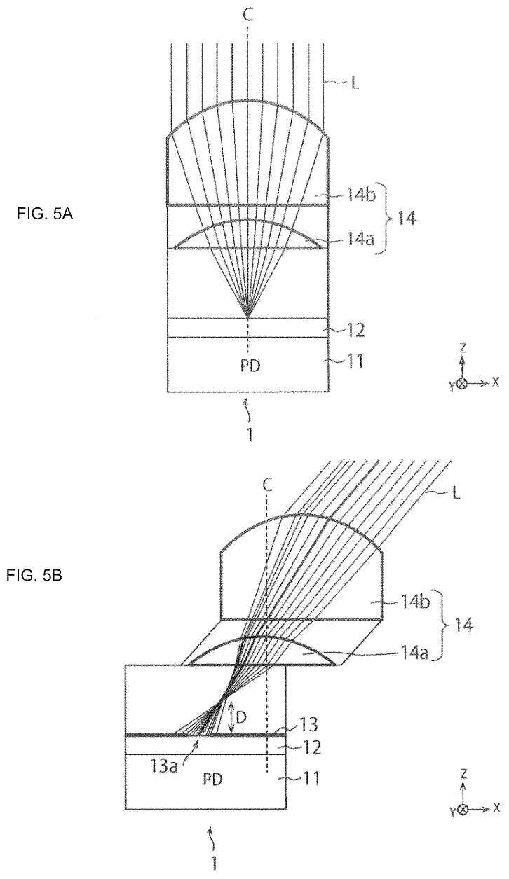

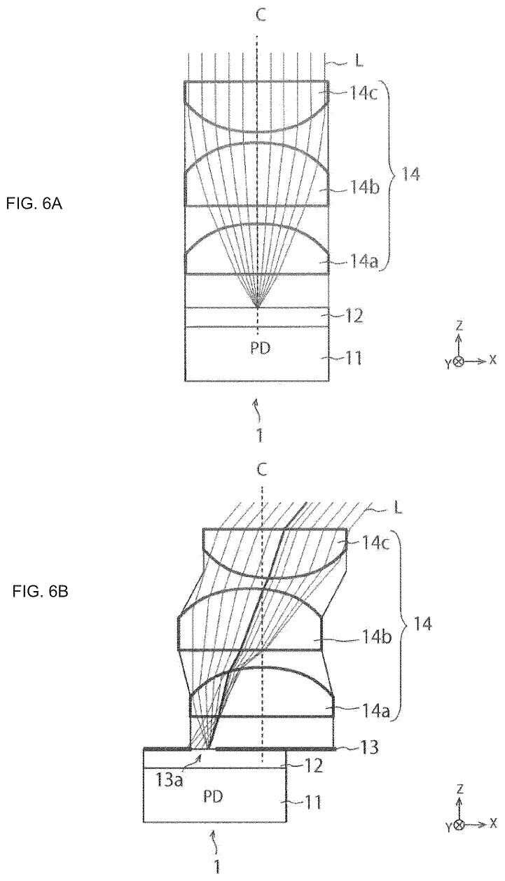

Next, the solid-state imaging device of the first embodiment is compared with the solid-state imaging device of the comparative example with reference to FIGS. 5 and 6.

FIG. 5 is a cross-sectional view for describing a function of a solid-state imaging device of a comparative example of the first embodiment.

A of FIG. 5 is a cross-sectional view for describing an operation of the optical system 14 of each pixel 1 of the present comparative example. In A of FIG. 5, the optical system 14 includes the lower lens 14a and the intermediate lens 14b, but does not include the upper lens 14c. In A of FIG. 5, light incident on the optical system 14 sequentially passes through the intermediate lens 14b and the lower lens 14a.

B of FIG. 5 is a cross-sectional view for describing an operation of the pinhole 13a of each pixel 1 of the present comparative example. In B of FIG. 5, the optical axis of the intermediate lens 14b and the pinhole 13a are provided at positions not overlapping with the optical axis C of the lower lens 14a. As a result, the light beam L transmitted through the optical system 14 intersects at a position higher than the upper surface of the light shielding layer 13 as indicated by reference sign D. In B of FIG. 5, the parallel light is incident on the upper surface of the intermediate lens 14b from a direction inclined by 41° with respect to the Z direction.

FIG. 6 is a cross-sectional view for describing a function of the solid-state imaging device of the first embodiment.

A of FIG. 6 is a cross-sectional view for describing an operation of the optical system 14 of each pixel 1 of the present embodiment. In A of FIG. 6, the optical system 14 includes the lower lens 14a, the intermediate lens 14b, and the upper lens 14c. In A of FIG. 6, light incident on the optical system 14 sequentially passes through the upper lens 14c, the intermediate lens 14b, and the lower lens 14a.

B of FIG. 6 is a cross-sectional view for describing an operation of the pinhole 13a of each pixel 1 of the present embodiment. In B of FIG. 6, the optical axis of the upper lens 14c, the optical axis of the intermediate lens 14b, and the pinhole 13a are provided at positions not overlapping with the optical axis C of the lower lens 14a. Specifically, the intermediate lens 14b and the upper lens 14c are alternately eccentric with respect to the lower lens 14a. In B of FIG. 6, the parallel light is incident on the upper surface of the upper lens 14c from a direction inclined by 41° with respect to the Z direction.

Comparing A of FIG. 5 with A of FIG. 6, the NA of A of FIG. 5 is 0.55, and the NA of A of FIG. 6 is 0.6. As described above, according to the present embodiment, the NA can be increased by providing the upper lens 14c having a shape concave toward the subject S side in the optical system 14. This makes it possible to reduce the light spot, and as a result, it is possible to set the diameter of the pinhole 13a to be small. Furthermore, by reducing the diameter of the pinhole 13a, the light beam L having an angle other than a desired angle can be preferably kicked by the light shielding layer 13, and angular resolution can be increased and high image quality can be achieved. Note that the images formed on the optical axis C in A of FIG. 5 and A of FIG. 6 are both formed with no aberration.

Comparing B of FIG. 5 with B of FIG. 6, in B of FIG. 5, a minimum spot appears at a position higher than the upper surface of the light shielding layer 13 due to the aberration, whereas in B of FIG. 6, a minimum spot appears at the height of the upper surface of the light shielding layer 13. That is, the minimum spot illustrated in B of FIG. 5 deviates from the height of the upper surface of the light shielding layer 13, whereas the minimum spot illustrated in B of FIG. 6 does not deviate from the height of the upper surface of the light shielding layer 13. Specifically, the minimum spot illustrated in B of FIG. 5 is located above the upper surface of the light shielding layer 13 by a distance D. Therefore, while 4 out of 12 light beams L are kicked in B of FIG. 5, only 2 out of 12 light beams L are kicked in B of FIG. 6. Therefore, according to the present embodiment, even if the pinhole 13a is provided at a position shifted from the optical axis C, it is possible to suppress a decrease in sensitivity of the pixel 1. In other words, according to the present embodiment, it is possible to reduce sensitivity differences between the pixel 1 at the center of the pixel array region 2 and the other pixels 1, thereby improving the image quality of the solid-state imaging device.

Next, referring again to FIG. 2, further details of the five pixels 1 illustrated in FIG. 2 will be described.

In each pixel 1 illustrated in FIG. 2, the optical system 14 includes the lower lens 14a, the intermediate lens 14b, and the upper lens 14c. The lower lens 14a and the intermediate lens 14b each have a shape convex toward the subject S side. On the other hand, the upper lens 14c has a shape concave toward the subject S side.

According to the present embodiment, by providing the upper lens 14c having a shape concave toward the subject S side in the optical system 14, it is possible to increase the NA of the optical system 14 and correct aberration of image formation. Moreover, according to the present embodiment, by providing the upper lens 14c as described above and the intermediate lens 14b having a shape convex toward the subject S side in the optical system 14, it is possible to bring the image formation closer to no aberration. Moreover, according to the present embodiment, by providing the upper lens 14c and the intermediate lens 14b as described above, and the lower lens 14a having a shape convex toward the subject S side in the optical system 14, it is possible to preferably collect light incident on the optical system 14 while bringing the image formation closer to no aberration. This state is exemplified in B of FIG. 6, for example.

In the pixel 1 having the angle of view of 0° and ±20° illustrated in FIG. 2, aberration correction capability of the optical system 14 is sufficiently high, so that the optical system 14 is disposed in a state without eccentricity. On the other hand, in the pixel 1 having the angle of view ±41°, the optical system 14 is disposed in an eccentric state in order to enhance the aberration correction capability of the optical system 14. Specifically, the intermediate lens 14b and the upper lens 14c are alternately eccentric with respect to the lower lens 14a. This makes it possible to improve the aberration correction capability of the optical system 14 in the pixel 1 having the angle of view ±41°.

According to the present embodiment, by disposing the light shielding layer 13 having the pinhole 13a between the photodetector PD of each pixel 1 and the optical system 14, it is possible to block excessive light by the light shielding layer 13 (see B of FIG. 4). In this case, there is a concern that light is restricted from entering the photodetector PD from multiple directions, and a spot of light is distorted. However, according to the present embodiment, by providing the lower lens 14a, the intermediate lens 14b, and the upper lens 14c in the optical system 14, it is possible to preferably collect the light incident on the optical system 14 while bringing the image formation closer to no aberration. This makes it possible to address the above concerns. That is, according to the present embodiment, it is possible to achieve a preferable structure in a case where the pinhole 13a is arranged between the photodetector PD and the optical system 14.

In the pixel 1 having the angles of view of ±20° and ±40° illustrated in FIG. 2, the pinhole 13a is provided at a position not overlapping with the optical axis C of the lower lens 14a. Thus, only light incident on the optical system 14 from a direction inclined by a desired angle with respect to the Z direction can pass through the pinhole 13a. As a result, the angle of view can be gradually given to these pixels 1 (see C of FIG. 4).

In each pixel 1 illustrated in FIG. 2, it is desirable that the angle θ between an upper light mean and a lower light beam in the optical system 14 has a value satisfying −10°≤θ≤10°. Here, positive θ represents a diverging direction, and positive θ represents a converging direction. The reason why the angle θ is set to 10° or less is to prevent information from being mixed between adjacent pixels 1. On the other hand, the reason why the angle θ is set to −10° or more is that it is hardly conceivable that the angle θ exceeds a light beam angle of an F value of 2.0.

Furthermore, in each pixel 1 illustrated in FIG. 2, a focal length f of the optical system 14 desirably has a value satisfying 0.0003 mm<f<3 mm. The reason why the focal length f is made longer than 0.0003 mm (0.3 μm) is that the limit of miniaturization of the pixels 1 is approximately 0.6 μm pitch. On the other hand, the reason why the focal length f is shorter than 3 mm (3000 μm) is to distinguish from a microscope, a telescope, and the like.

Furthermore, in each pixel 1 illustrated in FIG. 2, the diameter d of the pinhole 13a desirably has a value satisfying 0.02 μm<d<3 μm. The reason why the diameter d is longer than 0.02 μm is that light passes even if the diameter d is smaller than a wavelength due to plasmon phenomenon or the like, and in the present embodiment, a wavelength equal to or longer than visible light is assumed as the wavelength. On the other hand, the reason why the diameter d is shorter than 3 μm is that infrared rays are assumed to be handled. Note that the shape of the pinhole 13a may be a shape other than a circle (for example, a quadrangle such as a square or a rectangle). In this case, the above relationship is defined using a dimension other than the diameter d.

As described above, each pixel 1 of the present embodiment includes the photodetector PD, the light shielding layer 13, the optical system 14, and the like. In each pixel 1 of the present embodiment, the light shielding layer 13 includes the pinhole 13a as described above, and the optical system 14 includes the microlenses (the lower lens 14a, the intermediate lens 14b, and the upper lens 14c) as described above. Therefore, according to the present embodiment, it is possible to achieve a preferable structure in a case where the pinhole 13a is arranged between the photodetector PD and the optical system 14.

### Second Embodiment

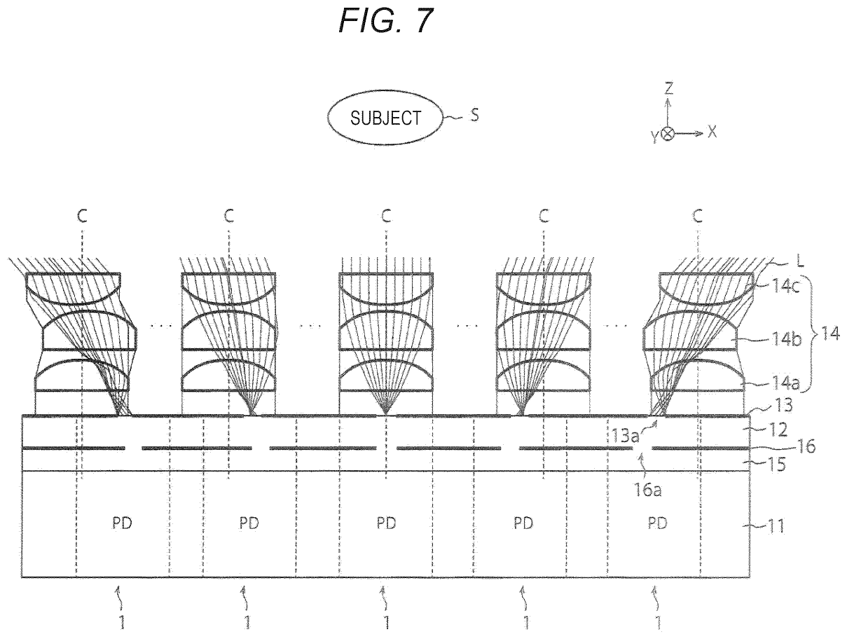

FIG. 7 is a cross-sectional view illustrating a structure of a solid-state imaging device of a second embodiment.

The solid-state imaging device of the present embodiment includes a transparent layer 15 and a light shielding layer 16 in addition to the components illustrated in FIG. 2. The transparent layer 15 is an example of a second transparent layer of the present disclosure. The light shielding layer 16 is an example of a second light shielding layer of the present disclosure. The light shielding layer 16 includes a pinhole 16a for each pixel 1. The pinhole 16a is an example of a second opening of the present disclosure.

The transparent layer 15 is provided on the substrate 11. As is the transparent layer 12, the transparent layer 15 is formed by a material capable of transmitting light. The transparent layer 15 is, for example, a SiO₂ film (silicon oxide film).

The light shielding layer 16 is provided on the transparent layer 15. As is the light shielding layer 13, the light shielding layer 16 is formed by a material capable of blocking light. The light shielding layer 16 is, for example, a metal layer such as a tungsten (W) layer. FIG. 7 illustrates five pinholes 16a included in five pixels 1. Light incident on the light shielding layer 16 of each pixel 1 passes through the pinhole 16a, passes through the transparent layer 15, and reaches the photodetector PD.

In each pixel 1 of the present embodiment, the optical system 14 is disposed above the substrate 11 via the transparent layer 15, the light shielding layer 16, the transparent layer 12, and the light shielding layer 13. In the present embodiment, the transparent layer 12 is provided on the light shielding layer 16, and the light shielding layer 13 is provided on the transparent layer 12.

In the present embodiment, light generated from the subject S and light reflected by the subject S are incident on the optical system 14 of each pixel 1. The light incident on the optical system 14 sequentially passes through the upper lens 14c, the intermediate lens 14b, and the lower lens 14a, and then is blocked by the light shielding layer 13 or passes through the pinhole 13a. The light having passed through the pinhole 13a passes through the transparent layer 12, and then is blocked by the light shielding layer 16 or passes through the pinhole 16a. The light having passed through the pinhole 16a passes through the transparent layer 15, reaches the photodetector PD, and is detected by the photodetector PD. In this way, the solid-state imaging device of the present embodiment can image the subject S similarly to the solid-state imaging device of the first embodiment.

In FIG. 7, as in FIG. 2, the positional relationship among the pinhole 13a, the lower lens 14a, the intermediate lens 14b, and the upper lens 14c in each pixel 1 is different for each pixel 1. Furthermore, the positional relationship between the pinhole 13a and the pinhole 16a in each pixel 1 is also different for each pixel 1. Details of these positional relationships will be described later.

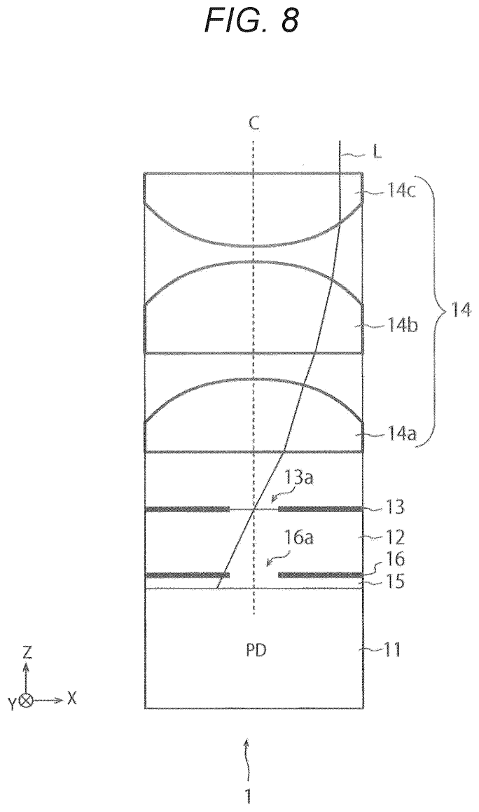

FIG. 8 is a cross-sectional view for describing a function of the solid-state imaging device of the second embodiment.

FIG. 8 illustrates a pixel 1 including the two pinholes 13a and 16a. Diameters of these pinholes 13a and 16a are, for example, 1.00 μm. In FIG. 8, light beam L incident on the upper lens 14c at an incident angle of 0.06° passes through the upper lens 14c, the intermediate lens 14b, and the lower lens 14a, and passes through pinhole 13a. The light beam L passes through a point on the optical axis C at the height of the pinhole 13a. On the other hand, the light beam L causes a center deviation of 1.08 μm before reaching the height of the pinhole 16a, and as a result, is kicked by the light shielding layer 16.

Therefore, according to the present embodiment, by providing the pinholes 13a and 16a in each pixel 1, the angular resolution can be improved as compared with the first embodiment. For example, the angular resolution of the present embodiment is about twice the angular resolution of the first embodiment.

Next, referring again to FIG. 7, further details of the five pixels 1 illustrated in FIG. 7 will be described.

In the pixel 1 having the angles of view of ±20° and ±40° illustrated in FIG. 7, the pinhole 13a is provided at a position not overlapping with the optical axis C of the lower lens 14a. This is similar to the pixel 1 with the angles of view of ±20° and ±40° illustrated in FIG. 2. Thus, only light incident on the optical system 14 from a direction inclined by a desired angle with respect to the Z direction can pass through the pinhole 13a. As a result, the angle of view can be gradually given to these pixels 1 (see C of FIG. 4).

Furthermore, in the pixel 1 having the angles of view of ±20° and ±40° illustrated in FIG. 7, the pinhole 16a is provided at a position not overlapping with the pinhole 13a in plan view. Thus, even in the pixel 1 having the angles of view of ±20° and ±40°, it is possible to obtain an operation similar to that of the pixel 1 (the pixel 1 having the angle of view of 0°) illustrated in FIG. 7. Therefore, according to the present embodiment, it is possible to improve the angular resolution while gradually giving the angle of view to these pixels 1.

The angle θ, the focal length f, and the diameter d described in the first embodiment are desirably set similarly to the first embodiment also in the present embodiment. The condition of 0.02 μm<d<3 μm may be applied not only to the diameter of the pinhole 13a but also to the diameter of the pinhole 16a. Note that the shape of the pinholes 13a and 16a may be a shape other than a circle (for example, a quadrangle such as a square or a rectangle). In this case, the above relationship is defined using a dimension other than the diameter d.

In the present embodiment, a thickness from the upper surface of the upper lens 14c to the upper surface of the light shielding layer 13 is approximately 9 μm, thicknesses of the transparent layers 12 and 15 are approximately 1 μm, and a thickness of the substrate 11 is approximately 3 μm. Furthermore, the diameters of the pinholes 13a and 16a of the present embodiment are approximately 0.24 μm.

As described above, each pixel 1 of the present embodiment includes the photodetectors PD, the light shielding layers 13 and 16, the optical system 14, and the like. In each pixel 1 of the present embodiment, the light shielding layers 13 and 16 respectively include the pinholes 13a and 16a as described above, and the optical system 14 includes the microlenses (the lower lens 14a, the intermediate lens 14b, and the upper lens 14c) as described above. Therefore, according to the present embodiment, it is possible to achieve a preferable structure in a case where the pinholes 13a and 16a are arranged between the photodetectors PD and the optical system 14.

### Third Embodiment

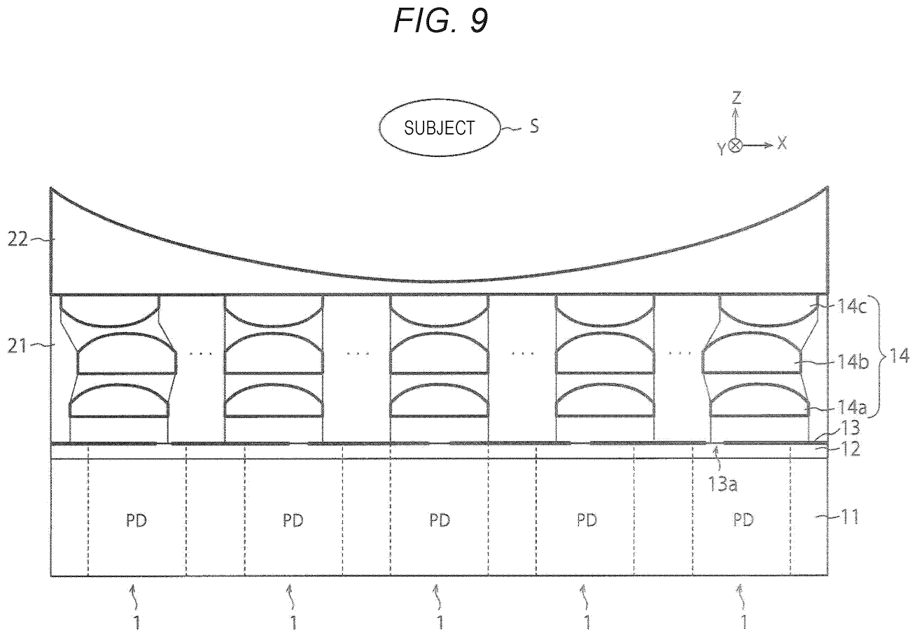

FIG. 9 is a cross-sectional view illustrating a structure of a solid-state imaging device of a third embodiment.

As in FIG. 2, FIG. 9 schematically illustrates a cross section of five pixels 1 in the pixel array region 2 illustrated in FIG. 1. The structure of these pixels 1 is similar to that of the first embodiment. In FIG. 9, a lens array 21 including the optical system 14 (microlens) of the pixel 1, and a common lens 22 provided above the lens array 21 are further provided.

The common lens 22 functions as a common lens for these pixels 1. Thus, the angle of view of the solid-state imaging device can be easily set large. The common lens 22 of the present embodiment has an upper surface having a shape concave toward the subject S side and a lower surface that is a flat surface. According to the present embodiment, since the upper surface of the common lens 22 is a concave surface, it is possible to achieve the angle of view as described above. The concave surface is continuously provided across the plurality of pixels 1. Furthermore, according to the present embodiment, since the lower surface of the common lens 22 is a flat surface, the common lens 22 can be disposed on the upper surface of the upper lens 14c of the plurality of pixels 1. According to the present embodiment, in addition to using the optical system 14 and the pinhole 13a of each pixel 1, the angle of view can be gradually given to these pixels 1 by using the common lens 22.

In the present embodiment, 400×533 pixels 1 are arranged in an area having dimensions of a short side of 2.4 mm, a long side of 3.2 mm, and a maximum radius of 2 mm. Further, the radius of curvature of the common lens 22 is set to 4.1 mm. Thus, it is possible to achieve a camera of 213,000 pixels with a maximum total angle of view of 40°.

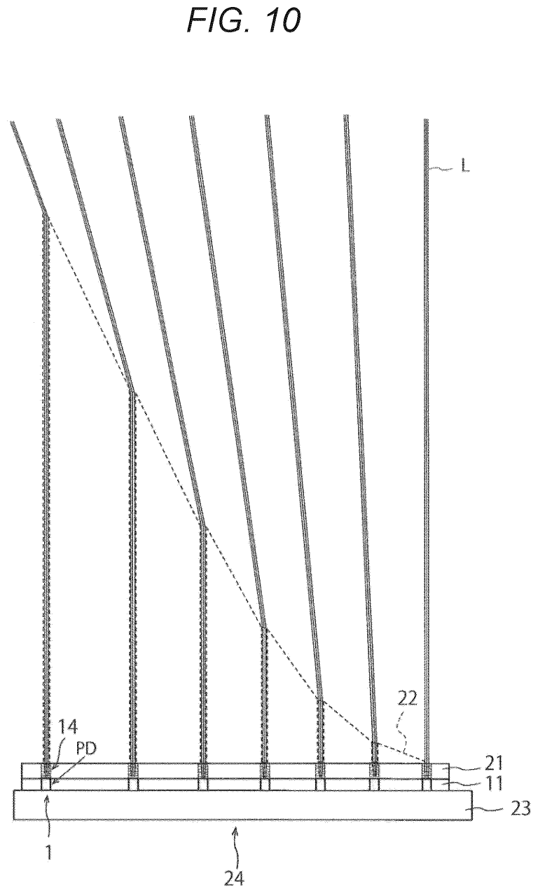

FIG. 10 is a cross-sectional view for describing a function of the solid-state imaging device of the third embodiment.

FIG. 10 illustrates some pixels 1 in the lens array 21, and further illustrates the shape of the upper surface (concave surface) of the common lens 22 by a broken line. FIG. 10 further illustrates a support substrate 23 supporting a substrate 11 and an imaging assembly 24 including the substrate 11, the lens array 21, the common lens 22, and the like. The solid-state imaging device of the present embodiment is configured in the form of the imaging assembly 24. FIG. 10 further illustrates paths of a plurality of light beams L incident on each pixel 1.

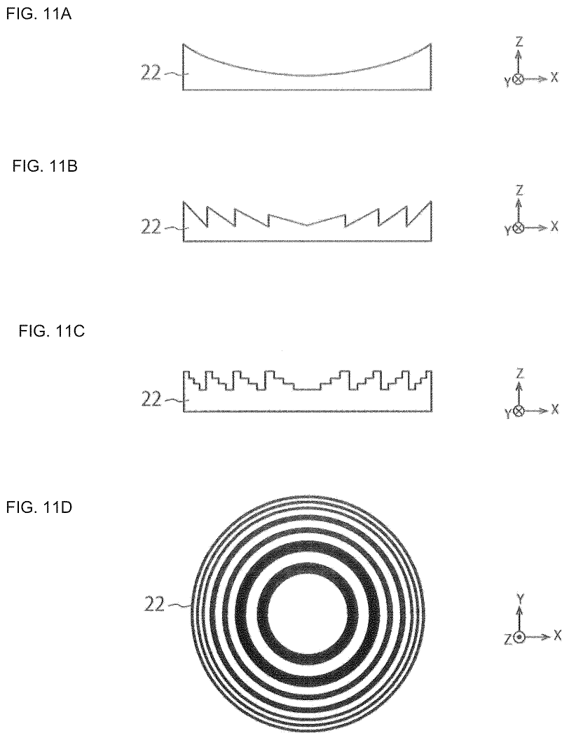

FIG. 11 is a cross-sectional view and a plan view for describing details of the solid-state imaging device of the third embodiment.

A of FIG. 11 illustrates the common lens 22 described above. The shape of the common lens 22 may be replaced with, for example, the shape illustrated in B of FIG. 11 or FIG. 11C. The common lens 22 illustrated in B of FIG. 11 is a Fresnel lens. The common lens 22 illustrated in C of FIG. 11 is a hologram element. D of FIG. 11 illustrates a planar shape of the hologram element. These Fresnel lens and the hologram element can be easily manufactured by a general semiconductor manufacturing process while having an operation similar to that of the common lens 22 (concave lens) illustrated in A of FIG. 11.

Note that the common lens 22 of the present embodiment may be a concave lens having a non-flat lower surface instead of a concave lens having a non-flat upper surface. Furthermore, the common lens 22 of the present embodiment may be a convex lens in which one of an upper surface and a lower surface is a flat surface and one of the upper surface and the lower surface is a non-flat surface. Furthermore, the common lens 22 of the present embodiment may be a lens other than a concave lens or a convex lens.

### Fourth Embodiment

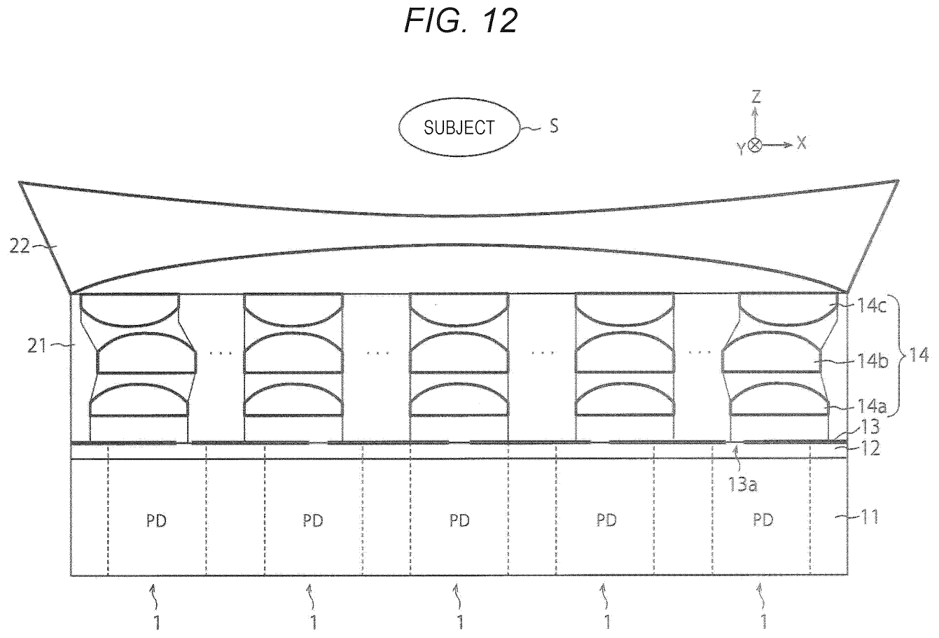

FIG. 12 is a cross-sectional view illustrating a structure of a solid-state imaging device of a fourth embodiment.

The solid-state imaging device (FIG. 12) of the present embodiment has a structure similar to that of the solid-state imaging device (FIG. 9) of the third embodiment. However, a common lens 22 of the present embodiment has an upper surface having a shape concave toward the subject S side and a lower surface having a shape convex toward the subject S side. According to the present embodiment, an angle of view similar to that of the third embodiment can be achieved by such an upper surface and a lower surface of the common lens 22. The common lens 22 of the present embodiment is, for example, a biconcave lens made by plastic, and a space between the lens array 21 and the common lens 22 is filled with air.

In the present embodiment, the radius of curvature of the common lens 22 is set to 9 mm and 4.25 mm, and a center thickness of the common lens 22 is set to 0.33 mm. Furthermore, a maximum distance between the lens array 21 and the common lens 22 in the Z direction is set to 0.71 mm.

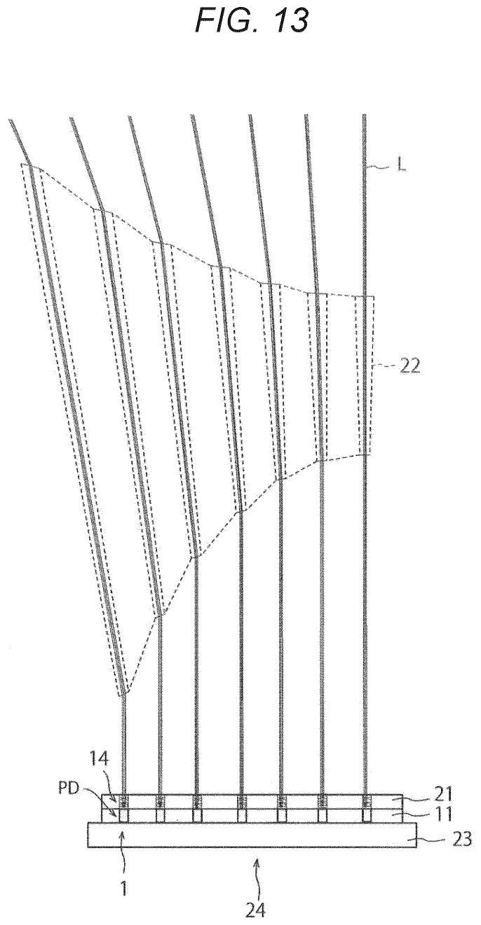

FIG. 13 is a cross-sectional view for describing a function of the solid-state imaging device of the fourth embodiment.

FIG. 13 illustrates some pixels 1 in the lens array 21, and further illustrates the shapes of the upper surface and the lower surface of the common lens 22 by broken lines. FIG. 13 further illustrates a support substrate 23 supporting substrate 11 and an imaging assembly 24 including the substrate 11, the lens array 21, the common lens 22, and the like. The solid-state imaging device of the present embodiment is also configured in the form of the imaging assembly 24. FIG. 13 further illustrates paths of a plurality of light beams L incident on each pixel 1.

FIG. 13 illustrates seven pixels 1. These pixels 1 are oriented in directions of angles of view of 0°, 3.4°, 6.9°, 10.6°, 14.5°, 18.8°, and 23.9°.

Note that the common lens 22 of the present embodiment may have an upper surface having a shape convex toward the subject S side. Furthermore, the common lens 22 of the present embodiment may have a lower surface having a concave shape toward the subject S side. Furthermore, the common lens 22 of the present embodiment may be a lens other than the biconcave lens.

### Fifth Embodiment

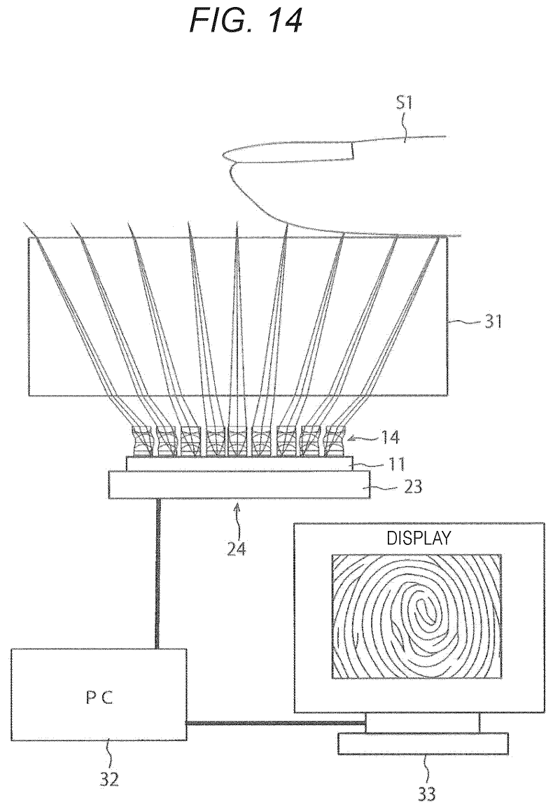

FIG. 14 is a schematic diagram illustrating a configuration of a solid-state imaging device of a fifth embodiment.

FIG. 14 illustrates an authentication device including an imaging assembly 24, which is a solid-state imaging device of the present embodiment, a glass cover 31, a personal computer (PC) 32, and a display 33. The glass cover 31 is an example of a transparent member of the present disclosure.

The authentication device of the present embodiment is a fingerprint sensor, and images a fingerprint of a finger S1 of the subject S by imaging assembly 24, and authenticates the subject S using an image obtained by the imaging. The imaging assembly 24 images the fingerprint of the finger S1 placed on the glass cover 31. The PC 32 performs image processing on an image obtained by imaging, thereby performing authentication. The display 33 displays an image of the fingerprint.

The solid-state imaging device (imaging assembly 24) of the present embodiment is the solid-state imaging device of any one of the first to fourth embodiments. Therefore, according to the present embodiment, highly accurate authentication can be performed using an image captured by a solid-state imaging device having a preferable structure. Furthermore, according to the present embodiment, since the vertical dimension (dimension in the Z direction described above) of the solid-state imaging device can be reduced, an under display type authentication device can be easily achieved. That is, it is possible to achieve an authentication device in which the finger S1 is placed on the horizontally disposed glass cover 31, and it is possible to achieve a structure suitable for the fingerprint sensor.

### Sixth Embodiment

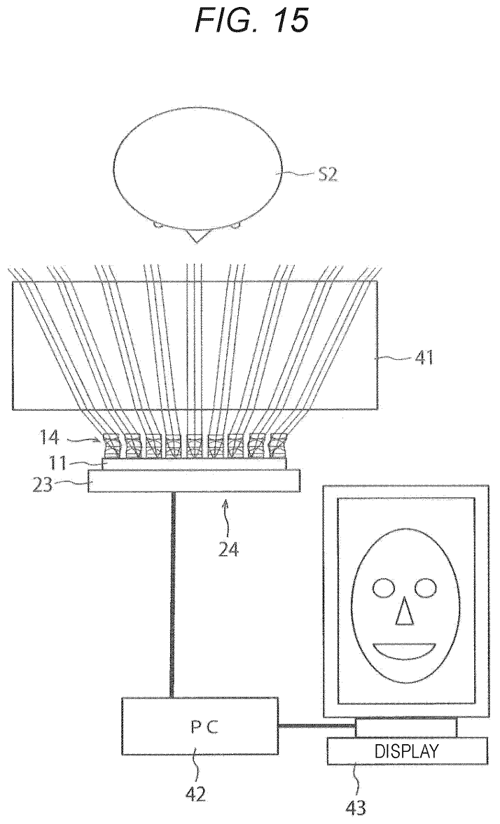

FIG. 15 is a schematic diagram illustrating a configuration of a solid-state imaging device of a sixth embodiment.

FIG. 15 illustrates an authentication device including an imaging assembly 24, which is a solid-state imaging device of the present embodiment, a glass cover 41, a PC 42, and a display 43. The glass cover 41 is an example of a transparent member of the present disclosure.

The authentication device of the present embodiment is a face authentication device (or an iris authentication device), captures an image of the face S2 of the subject S by the imaging assembly 24, and authenticates the subject S using the image obtained by the imaging. The imaging assembly 24 images a face S2 in front of the glass cover 41. The PC 42 performs image processing on an image obtained by imaging, thereby performing authentication. The display 43 displays an image of the face S2.

The solid-state imaging device (imaging assembly 24) of the present embodiment is the solid-state imaging device of any one of the first to fourth embodiments. Therefore, according to the present embodiment, highly accurate authentication can be performed using an image captured by a solid-state imaging device having a preferable structure. Furthermore, according to the present embodiment, since the vertical dimension (dimension in the Z direction described above) of the solid-state imaging device can be reduced, for example, a wall-mounted authentication device can be easily achieved. That is, it is possible to achieve an authentication device that directs the face S2 toward the glass cover 42 disposed vertically, and it is possible to achieve a structure suitable for the face authentication device (or the iris authentication device).

### Seventh Embodiment

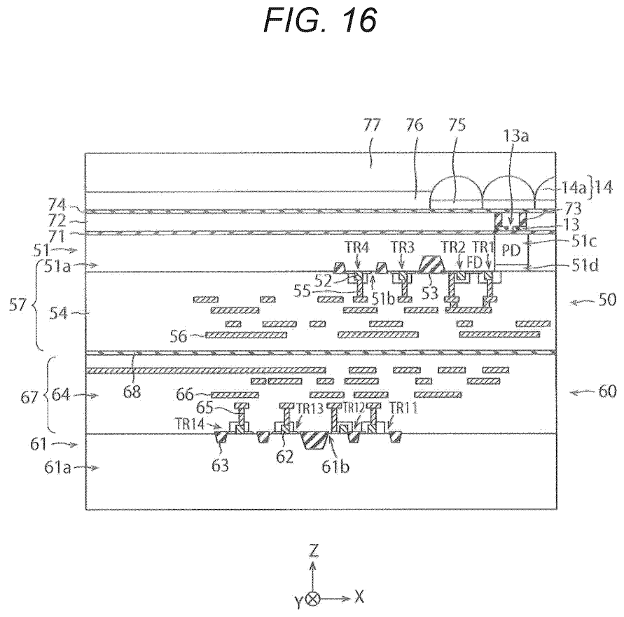

FIG. 16 is a cross-sectional view illustrating a structure of a solid-state imaging device of a seventh embodiment. The solid-state imaging device of the present embodiment corresponds to an example of the solid-state imaging device of the first embodiment. The solid-state imaging device of the present embodiment is a back-illuminated MOS solid-state imaging device.

The solid-state imaging device of the present embodiment is manufactured by bonding an upper substrate 50 and a lower substrate 60. In FIG. 16, the upper substrate 50 is disposed on the lower substrate 60. The upper substrate 50 and the lower substrate 60 are electrically connected to each other.

The upper substrate 50 includes a substrate 51, gate electrodes 52 of transistors TR1 to TR4, an element isolation insulating film 53, an interlayer insulating film 54, a plurality of contact plugs 55, and a plurality of wiring layers 56. The upper substrate 50 includes a multilayer wiring structure 57 including the contact plugs 55 and the wiring layers 56.

The substrate 51 is, for example, a semiconductor substrate such as a Si substrate. The substrate 51 corresponds to an example of the substrate 11 described above. The substrate 51 includes a well region 51a, source/drain regions 51b of the transistors TR1 to TR4, an n-type semiconductor region 51c of a photodetector PD, and a p-type semiconductor region 51d of the photodetector PD. The substrate 51 further includes a floating diffusion portion FD.

The lower substrate 60 includes a substrate 61, gate electrodes 62 of transistors TR11 to TR14, an element isolation insulating film 63, an interlayer insulating film 64, a plurality of contact plugs 65, and a plurality of wiring layers 66. The lower substrate 60 includes a multilayer wiring structure 67 including the contact plugs 65 and the wiring layers 66. The lower substrate 60 further includes a warp correction film 68.

The substrate 61 is, for example, a semiconductor substrate such as a Si substrate. The substrate 61 includes a well region 61a and source/drain regions 61b of the transistors TR11 to TR14.

The solid-state imaging device of the present embodiment further includes, on the upper substrate 50, an antireflection film 71, an insulating film 72, a light shielding layer 73, a planarization film 74, a color filter 75 for each optical system 14, a lens material 76, and a planarization film 77. The solid-state imaging device of the present embodiment further includes the above-described light shielding layer 13 and a pinhole 13a provided in the light shielding layer 13.

FIG. 16 illustrates the lower lens 14a of the optical system 14, but does not illustrate the intermediate lens 14b and the upper lens 14c of the optical system 14. The intermediate lens 14b and the upper lens 14c of the present embodiment will be described later.

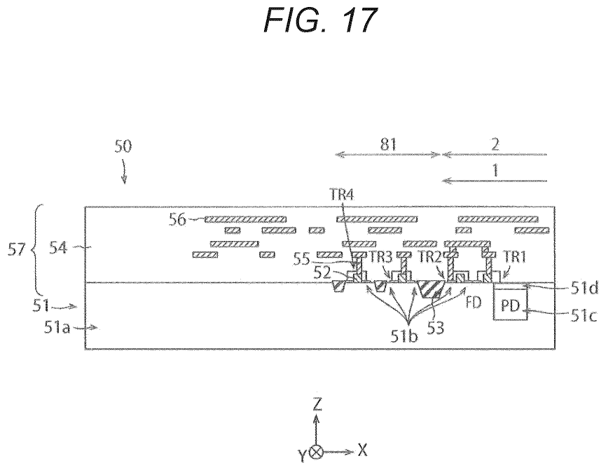

FIGS. 17 to 28 are cross-sectional views illustrating a method of manufacturing the solid-state imaging device of the seventh embodiment.

First, the upper substrate 50 is formed by forming various layers and the like illustrated in FIG. 16 on the substrate 51 or in the substrate 51 (FIG. 17). As a result, the image sensor in a semi-product state, that is, the pixel array region 2 and a control circuit 81 are formed. FIG. 17 further illustrates one pixel 1 in the pixel array region 2. The substrate 51 illustrated in FIG. 17 is a semiconductor wafer before being diced into a semiconductor chip.

Specifically, in a region to be a chip in the substrate 51, the source/drain regions 51b of the transistors TR1 to TR4, the n-type semiconductor region 51c of the photodetector PD, and the p-type semiconductor region 51d of the photodetector PD are formed. These are formed in the well region 51a of the substrate 51. The well region 51a is formed by introducing impurity atoms of a first conductivity type (for example, p-type) into the substrate 51, and the source/drain region 51b is formed by introducing impurity atoms of a second conductivity type (for example, n-type) into the substrate 51. The source/drain region 51b, the n-type semiconductor region 51c, the p-type semiconductor region 51d, and the floating diffusion portion FD are formed by performing ion implantation from the surface of the substrate 51 into the substrate 51.

The gate electrodes 52 are formed on the substrate 51 via a gate insulating film. The transistors TR1 and TR2 are part of the plurality of pixel transistors included in the pixel 1. The transistor TR1 adjacent to the photodetector PD is a transfer transistor. In the present embodiment, a source region or a drain region of the transistor TR1 is the floating diffusion portion FD. The pixels 1 are separated from each other by an element isolation insulating film 53 formed in the substrate 51. The transistors TR3 and TR4 constitute the control circuit 81.

Next, a first interlayer insulating film 54 is formed on the substrate 51, a plurality of contact holes is formed in the first interlayer insulating film 54, and the contact plugs 55 are formed in these contact holes. When the contact plugs 55 having different heights are formed, a first insulating thin film (for example, a silicon oxide film) is formed on upper surfaces of the substrate 51 and the gate electrodes 52, a second insulating thin film (for example, a silicon nitride film) serving as an etching stopper is formed on the first insulating thin film, and the first interlayer insulating film 54 is formed on the second insulating thin film. Thereafter, contact holes having different depths are selectively formed in the first interlayer insulating film 54 up to the second insulating thin film serving as an etching stopper. Furthermore, the contact hole is processed by selectively etching the first and second insulating thin films having the same film thickness in each portion so as to be continuous with each contact hole. Then, a conductor to be a material of the contact plugs 55 is embedded in each contact hole.

Next, first to third wiring layers 56 and second to fourth interlayer insulating films 54 are alternately formed on the first interlayer insulating film 54. As a result, the multilayer wiring structure 57 is formed. These wiring layers 56 are formed so as to be electrically connected to the contact plugs 55. These wiring layers 56 are, for example, metal wiring layers including a barrier metal layer and a Cu (copper) layer. The barrier metal layer is formed before the Cu layer of each wiring layer 56 is formed in order to prevent diffusion of Cu atoms. Note that the number of the wiring layers 56 in the multilayer wiring structure 57 may be other than 3, and each wiring layer 56 may include a metal layer other than the Cu layer.

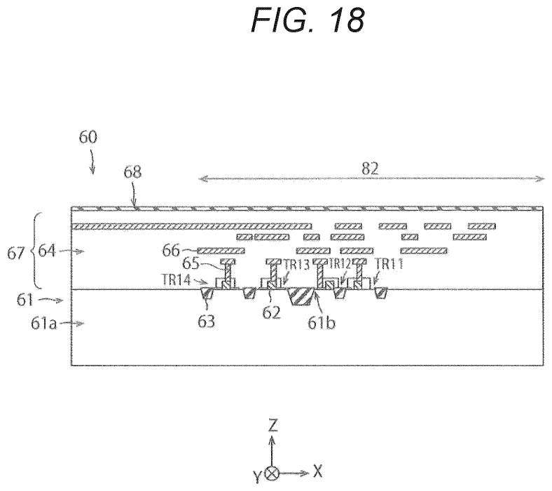

Next, the lower substrate 60 is formed by forming various layers and the like illustrated in FIG. 16 on the substrate 61 and in the substrate 61 (FIG. 18). As a result, a logic chip in the semi-product state, that is, a logic circuit 82 is formed. The substrate 61 illustrated in FIG. 18 is a semiconductor wafer before being diced into a semiconductor chip.

Specifically, the source/drain regions 61b of the transistors TR11 to TR14 are formed in a region to be a chip in the substrate 61. The source/drain region 61b is formed in the well region 61a of the substrate 61. The well region 61a is formed by introducing impurity atoms of the first conductivity type (for example, p-type) into the substrate 61, and the source/drain region 61b is formed by introducing impurity atoms of the second conductivity type (for example, n-type) into the substrate 61. The source/drain region 61b is formed by performing ion implantation from the surface of the substrate 61 into the substrate 61.

The gate electrode 62 is formed on the substrate 61 via a gate insulating film. The transistors TR11, TR12, TR13, TR14 are separated by an element isolation insulating film 63 formed in the substrate 61. The logic circuit 82 can be configured by a CMOS transistor formed by the transistors TR11, TR12, TR13, and TR14.

Next, a first interlayer insulating film 64 is formed on the substrate 61, a plurality of contact holes is formed in the first interlayer insulating film 64, and the contact plugs 65 are formed in these contact holes. When the contact plugs 65 having different heights are formed, a first insulating thin film (for example, a silicon oxide film) is formed on upper surfaces of the substrate 61 and the gate electrodes 62, a second insulating thin film (for example, a silicon nitride film) serving as an etching stopper is formed on the first insulating thin film, and the first interlayer insulating film 64 is formed on the second insulating thin film. Thereafter, contact holes having different depths are selectively formed in the first interlayer insulating film 64 up to the second insulating thin film serving as an etching stopper. Furthermore, the contact hole is processed by selectively etching the first and second insulating thin films having the same film thickness in each portion so as to be continuous with each contact hole. Then, a conductor to be a material of the contact plugs 65 is embedded in each contact hole.

Next, first to fourth wiring layers 66 and second to fifth interlayer insulating films 64 are alternately formed on the first interlayer insulating film 64. As a result, the multilayer wiring structure 67 is formed. These wiring layers 66 are formed so as to be electrically connected to the contact plugs 65. These wiring layers 66 are, for example, metal wiring layers including a barrier metal layer and a Cu (copper) layer. The barrier metal layer is formed before the Cu layer of each wiring layer 66 is formed in order to prevent diffusion of Cu atoms. Note that the number of the wiring layers 56 in the multilayer wiring structure 67 may be other than 4, and each wiring layer 66 may include a metal layer other than the Cu layer.

Next, a warp correction film 68 for reducing warp at the time of bonding the upper substrate 50 and the lower substrate 60 is formed on the fourth interlayer insulating film 64.

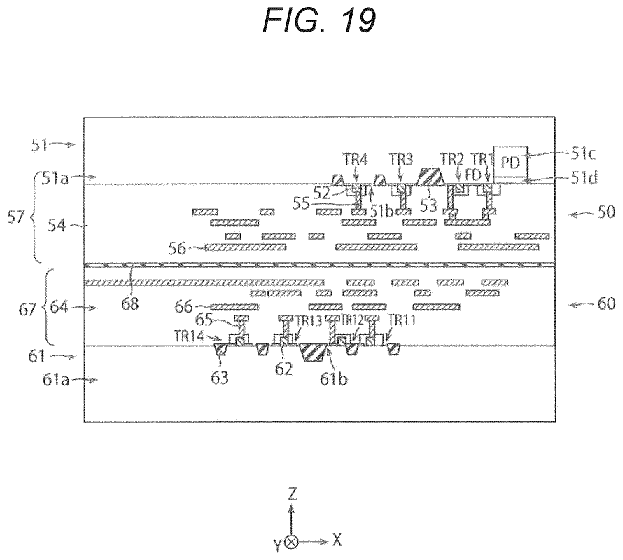

Next, the upper substrate 50 and the lower substrate 60 are bonded to each other in such a manner that the interlayer insulating film 54 and the interlayer insulating film 64 face each other (FIG. 19). The bonding is performed using, for example, an adhesive, but may be performed by plasma bonding.

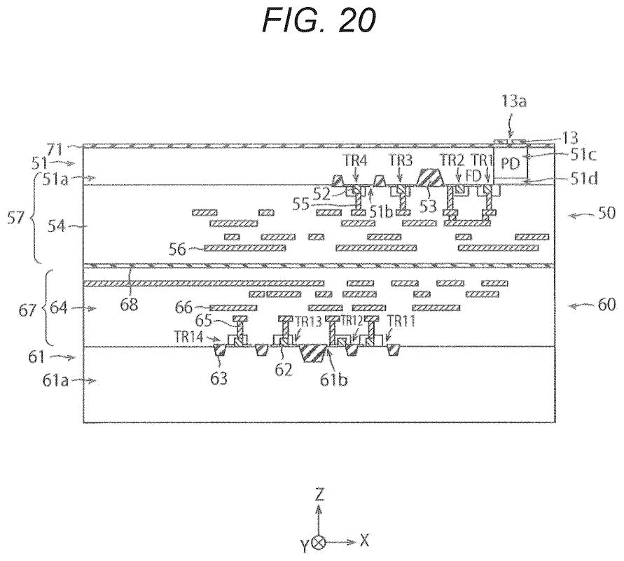

Next, the substrate 51 is ground and polished from the back surface side of the substrate 51 to thin the substrate 51 (FIG. 20). This thinning is performed to expose the photodetector PD on the back surface of the substrate 51. After the thinning, a p-type semiconductor layer (not illustrated) for suppressing dark current is formed on a back surface of the photodetector PD. For example, a thickness of the substrate 51 before thinning is approximately 600 μm, and a thickness of the substrate 51 after thinning is approximately 3 to 5 μm. Next, the back surface of the substrate 51 becomes a light incident surface of a back-illuminated solid-state imaging device.

Next, the antireflection film 71 is formed on the substrate 51 (C of FIG. 20). The antireflection film 71 corresponds to an example of the above-described transparent layer 12.

Next, the light shielding layer 13 is formed on the photodetector PD via the antireflection film 71 (FIG. 20). The light shielding layer 13 is, for example, a tungsten (W) layer. Here, for example, the light shielding layer 13 having a thickness of 350 nm is formed. Next, the surface of the light shielding layer 13 is polished by chemical mechanical polishing (CMP), and thereafter, a pinhole 13a is formed in the light shielding layer 13 by etching (FIG. 20).

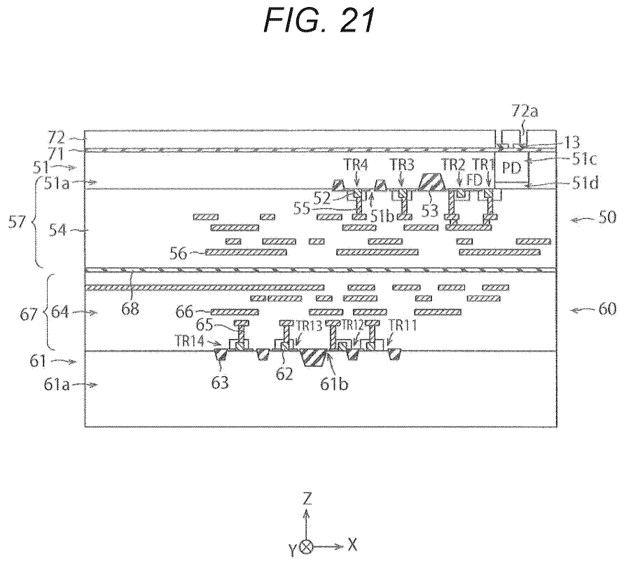

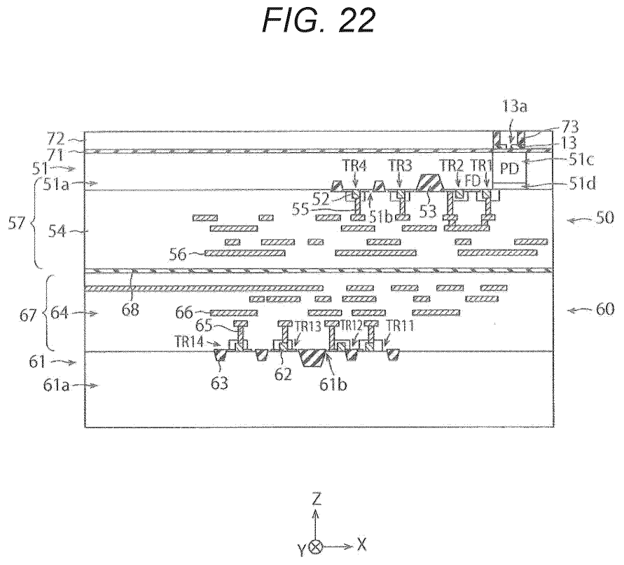

Next, the insulating film 72 is formed on the antireflection film 71 and the light shielding layer 13, a light shielding groove 72a is formed in the insulating film 72 by etching, and the light shielding layer 73 is formed in the light shielding groove 72a (FIG. 21, FIG. 22). The light shielding groove 72a is formed at a depth not reaching the substrate 51. The light shielding layer 73 is formed by forming a tungsten (W) layer on the insulating film 72 and polishing the surface of the W layer by CMP. The W layer outside the light shielding groove 72a is removed by CMP, and the W layer remains in the light shielding groove 72a. The W layer in the light shielding groove 72a is the light shielding layer 73.

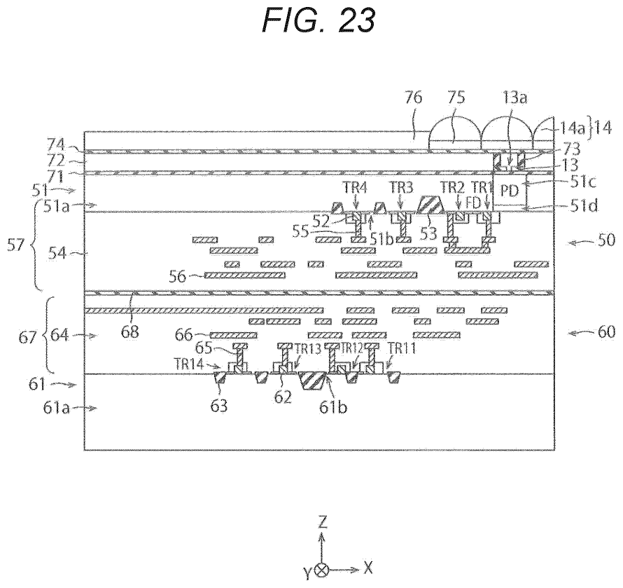

Next, the planarization film 74 is formed on the entire surface of the substrate 51, and the color filter 75 of each pixel 1 is formed on the planarization film 74 (FIG. 23). For example, the red (R), green (G), and blue (B) color filters 75 are formed for the red (R), green (G), and blue (B) pixels 1, respectively. Each color filter 75 is formed above the corresponding photodetector PD by forming an organic film containing a pigment or dye of a desired color and patterning the organic film.

Next, the lens material 76 is formed on the entire surface of the substrate 51, a resist film (not illustrated) is formed on the lens material 76, and the lens material 76 is processed by etching using the resist film as a mask (FIG. 23). As a result, the lower lens 14a of optical system 14 is formed on each color filter 75.

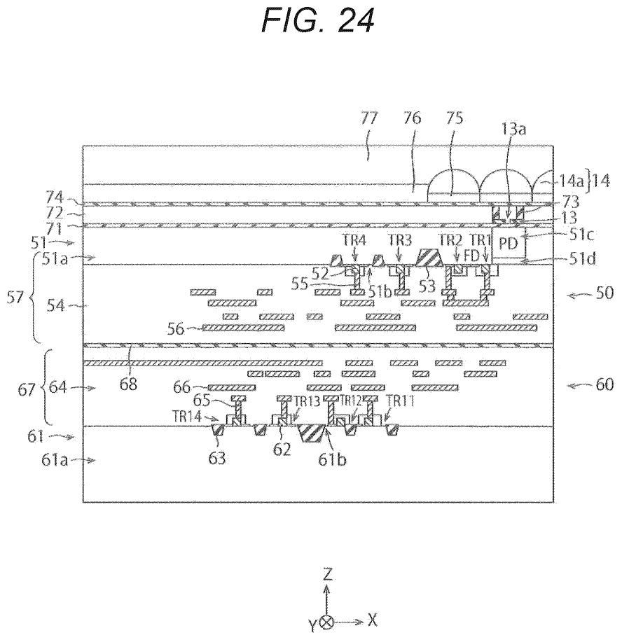

Next, the planarization film 77 is formed on the entire surface of the substrate 51 (FIG. 24). Thus, the structure illustrated in FIG. 16 is completed. Thereafter, the intermediate lens 14b and the upper lens 14c of optical system 14 are formed.

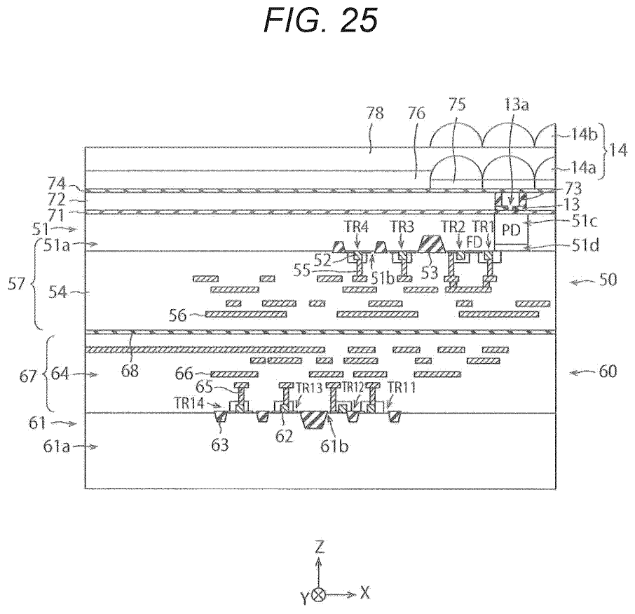

FIG. 25 illustrates the planarization film 77 obtained by thinning the planarization film 78. Next, the intermediate lens 14b of each pixel 1 is formed on the planarization film 78 (FIG. 25). The method of forming the intermediate lens 14b is similar to the method of forming the lower lens 14a. FIG. 25 illustrates three intermediate lenses 14b formed above the three lower lenses 14a.

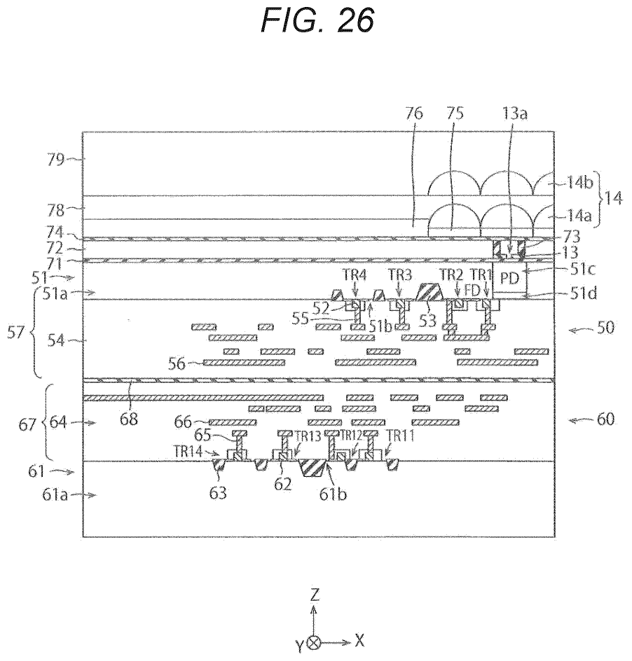

Next, a planarization film (not illustrated) is formed on the entire surface of the substrate 51, and the lens material 79 is formed on the planarization film (FIG. 26). The lens material 79 of the present embodiment has a refractive index close to the refractive index of the planarization film.

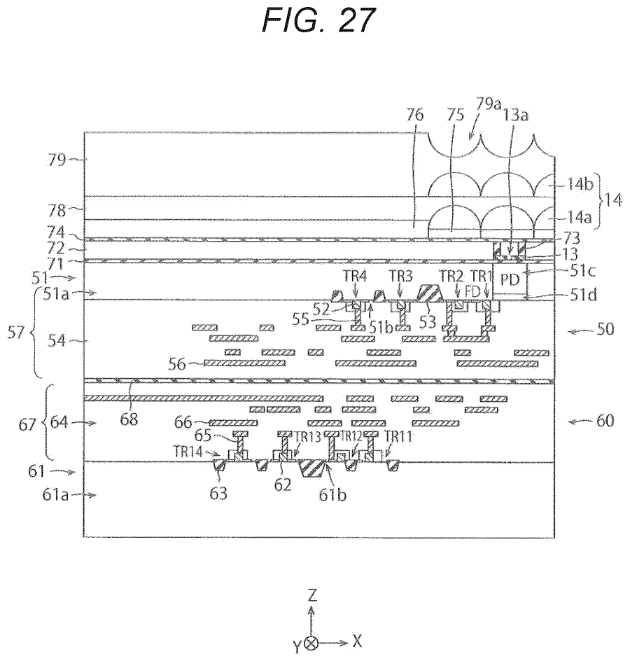

Next, a resist film (not illustrated) is formed on the lens material 79, and the lens material 79 is processed by etching using the resist film as a mask (FIG. 27). As a result, a concave portion 79a is formed in the lens material 79 above each intermediate lens 14b.

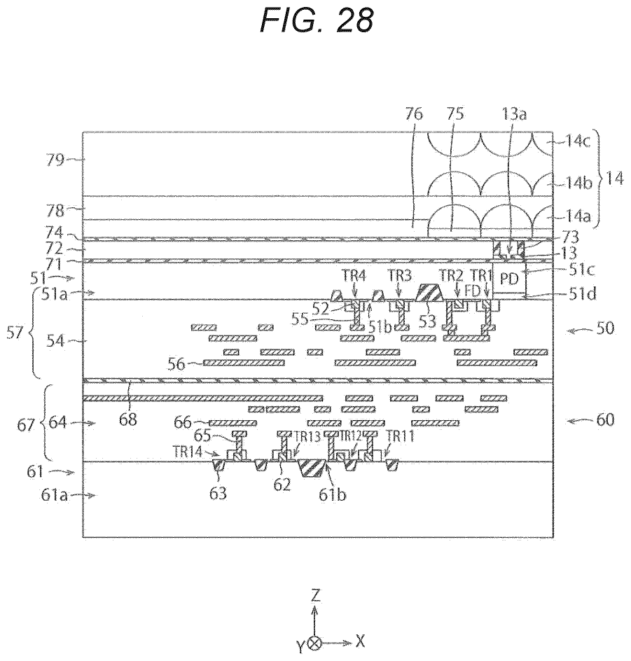

Next, the upper lens 14c is formed in each concave portion 79a (FIG. 28). As a result, the optical system 14 of each pixel 1 is formed. FIG. 28 illustrates three upper lenses 14c formed above the three intermediate lenses 14b. The upper lens 14c of the present embodiment is formed by a material having a refractive index higher than that of the lens material 79.

In this way, the solid-state imaging device of the present embodiment is manufactured.

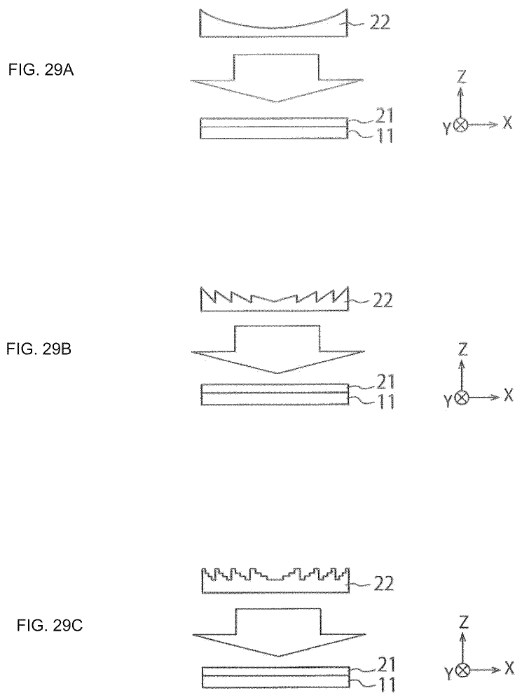

FIG. 29 is a cross-sectional view illustrating details of the method of manufacturing the solid-state imaging device of the seventh embodiment.

A of FIG. 29 illustrates the substrate 11 and the lens array 21 described in the third or fourth embodiment. In the present embodiment, the common lens 22 may be disposed on the lens array 21 after the steps illustrated in FIGS. 17 to 28 are performed. The common lens 22 illustrated in A of FIG. 29 is a concave lens. The common lens 22 may be a Fresnel lens or a hologram element instead of the concave lens (B and C in FIG. 29).

According to the present embodiment, it is possible to manufacture the solid-state imaging device of the first embodiment and the like. Note that, in manufacturing the solid-state imaging device of the second embodiment, it is sufficient if a step of forming the light shielding layer 13 is performed similarly to the step of forming the light shielding layer 16.

According to each of the above embodiments, for example, it is possible to lengthen a focal depth, prevent a focal point from flying even by vibration, and suppress fluctuation in performance due to temperature. Further, it is possible to miniaturize the solid-state imaging device, manufacture the components of the solid-state imaging device only by a semiconductor process, and achieve high NA and excellent angular resolution. Furthermore, it is possible to reduce optical aberration, eliminate the need for large positions of the lenses 14a to 14c up to a half angle of view) (30°, and achieve a wide-angle lensless camera.

According to each of the above embodiments, for example, it is possible to achieve preferable imaging by using the microlenses without using an imaging camera. According to each of the above embodiments, for example, various authentication devices and other devices (for example, an Eye-Tracking device and the like) can be suitably implement.

### Application Example

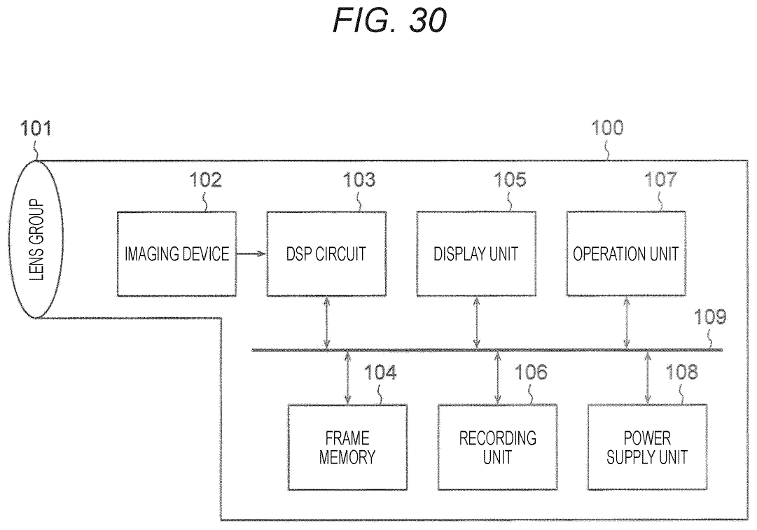

FIG. 30 is a block diagram illustrating a configuration example of an electronic device. The electronic device illustrated in FIG. 30 is a camera 100.

The camera 100 includes an optical unit 101 including a lens group and the like, an imaging device 102 that is the solid-state imaging device according to any of the first to seventh embodiments, a digital signal processor (DSP) circuit 103 that is a camera signal processing circuit, a frame memory 104, a display unit 105, a recording unit 106, an operation unit 107, and a power supply unit 108. Furthermore, the DSP circuit 103, the frame memory 104, the display unit 105, the recording unit 106, the operation unit 107, and the power supply unit 108 are connected to each other via a bus line 109.

The optical unit 101 captures incident light (image light) from a subject and forms an image on an imaging surface of the imaging device 102. The imaging device 102 converts an amount of incident light formed into an image on the imaging surface by the optical unit 101 into an electric signal on a pixel-by-pixel basis and outputs the electric signal as a pixel signal.

The DSP circuit 103 performs signal processing on the pixel signal output from the imaging device 102. The frame memory 104 is a memory for storing one screen of a moving image or a still image captured by the imaging device 102.

The display unit 105 includes, for example, a panel type display device such as a liquid crystal panel or an organic EL panel, and displays a moving image or a still image captured by the imaging device 102. The recording unit 106 records a moving image or a still image captured by the imaging device 102 on a recording medium such as a hard disk or a semiconductor memory.

The operation unit 107 issues operation commands for various functions of the camera 100 in response to an operation performed by a user. The power supply unit 108 appropriately supplies various power supplies, which are operation power supplies for the DSP circuit 103, the frame memory 104, the display unit 105, the recording unit 106, and the operation unit 107, to these power supply targets.

It can be expected to acquire a satisfactory image by using the solid-state imaging device according to any of the first to seventh embodiments as the imaging device 102.

The solid-state imaging device can be applied to various other products. For example, the solid-state imaging device may be mounted on any type of mobile bodies such as vehicles, electric vehicles, hybrid electric vehicles, motorcycles, bicycles, personal mobility, airplanes, drones, ships, and robots.

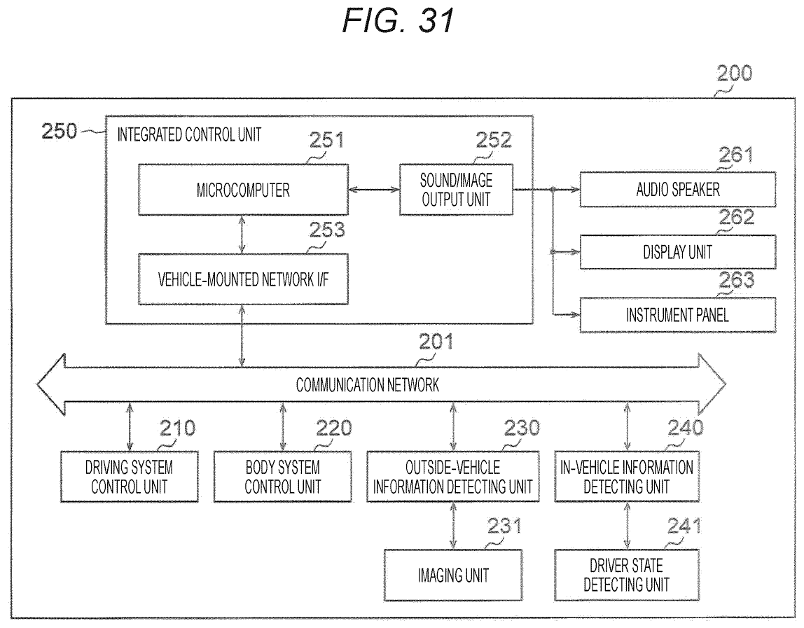

FIG. 31 is a block diagram illustrating a configuration example of a mobile body control system. The mobile body control system illustrated in FIG. 31 is a vehicle control system 200.

The vehicle control system 200 includes a plurality of electronic control units connected to each other via a communication network 201. In the example illustrated in FIG. 31, the vehicle control system 200 includes a driving system control unit 210, a body system control unit 220, an outside-vehicle information detecting unit 230, an in-vehicle information detecting unit 240, and an integrated control unit 250. Moreover, FIG. 31 illustrates a microcomputer 251, a sound/image output unit 252, and a vehicle-mounted network interface (I/F) 253 as components of the integrated control unit 250.

The driving system control unit 210 controls the operation of devices related to a driving system of a vehicle in accordance with various types of programs. For example, the driving system control unit 210 functions as a control device for a driving force generating device for generating a driving force of a vehicle, such as an internal combustion engine, a driving motor, or the like, a driving force transmitting mechanism for transmitting the driving force to wheels, a steering mechanism for adjusting a steering angle of the vehicle, a braking device for generating a braking force of the vehicle, and the like.

The body system control unit 220 controls the operation of various types of devices provided to a vehicle body in accordance with various types of programs. For example, the body system control unit 220 functions as a control device for a smart key system, a keyless entry system, a power window device, or various types of lamps (for example, a head lamp, a backup lamp, a brake lamp, a turn signal, a fog lamp, or the like). In this case, radio waves transmitted from a mobile device as an alternative to a key or signals of various types of switches can be input to the body system control unit 220. The body system control unit 220 receives inputs of such radio waves or signals, and controls a door lock device, the power window device, the lamps, or the like of the vehicle.

The outside-vehicle information detecting unit 230 detects information on the outside of the vehicle including the vehicle control system 200. The outside-vehicle information detecting unit 230 is connected with, for example, an imaging unit 231. The outside-vehicle information detecting unit 230 makes the imaging unit 231 capture an image of the outside of the vehicle, and receives the captured image from the imaging unit 231. On the basis of the received image, the outside-vehicle information detecting unit 230 may perform processing of detecting an object such as a human, an automobile, an obstacle, a sign, a character on a road surface, or the like, or processing of detecting a distance thereto.

The imaging unit 231 is an optical sensor that receives light and that outputs an electric signal corresponding to the amount of received light. The imaging unit 231 can output the electric signal as an image, or can output the electric signal as information on a measured distance. The light received by the imaging unit 231 may be visible light, or may be invisible light such as infrared rays or the like. The imaging unit 231 includes the solid-state imaging device according to any of the first to seventh embodiments.

The in-vehicle information detecting unit 240 detects information on the inside of the vehicle equipped with the vehicle control system 200. The in-vehicle information detecting unit 240 is, for example, connected with a driver state detecting unit 241 that detects a state of a driver. For example, the driver state detecting unit 241 includes a camera that captures an image of the driver, and on the basis of detection information input from the driver state detecting unit 241, the in-vehicle information detecting unit 240 may calculate a degree of fatigue of the driver or a degree of concentration of the driver, or may determine whether or not the driver is dozing off. The camera may include the solid-state imaging device according to any of the first to seventh embodiments, and may be, for example, the camera 100 illustrated in FIG. 30.

The microcomputer 251 can calculate a control target value for the driving force generating device, the steering mechanism, or the braking device on the basis of the information on the inside or outside of the vehicle obtained by the outside-vehicle information detecting unit 230 or the in-vehicle information detecting unit 240, and output a control command to the driving system control unit 210. For example, the microcomputer 251 can perform cooperative control intended to implement functions of an advanced driver assistance system (ADAS), the functions including collision avoidance or shock mitigation for the vehicle, following traveling based on a following distance, vehicle speed maintaining traveling, a warning of collision of the vehicle, a warning of deviation of the vehicle from a lane, and the like.

Furthermore, the microcomputer 251 can perform cooperative control intended for automated driving, which makes the vehicle travel autonomously without depending on the operation of the driver, or the like, by controlling the driving force generating device, the steering mechanism, the braking device, or the like on the basis of the information on the outside or inside of the vehicle obtained by the outside-vehicle information detecting unit 230 or the in-vehicle information detecting unit 240.

Furthermore, the microcomputer 251 can output a control command to the body system control unit 220 on the basis of the information on the outside of the vehicle obtained by the outside-vehicle information detecting unit 230. For example, the microcomputer 251 can perform cooperative control for the purpose of preventing glare, such as switching from a high beam to a low beam, by controlling the headlamp according to the position of a preceding vehicle or an oncoming vehicle detected by the outside-vehicle information detecting unit 230.

The sound/image output unit 252 transmits an output signal of at least one of a sound or an image to an output device that can visually or auditorily provide information to an occupant of the vehicle or the outside of the vehicle. In the example of FIG. 31, an audio speaker 261, a display unit 262, and an instrument panel 263 are illustrated as such an output device. The display unit 262 may, for example, include an on-board display or a head-up display.

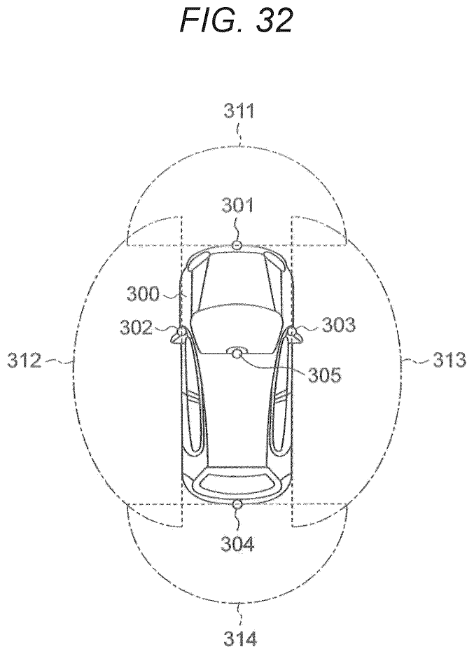

FIG. 32 is a plan view illustrating a specific example of a setting position of the imaging unit 231 in FIG. 31.

A vehicle 300 illustrated in FIG. 32 includes imaging units 301, 302, 303, 304, and 305 as the imaging unit 231. The imaging units 301, 302, 303, 304, and 305 are, for example, provided at positions on a front nose, side mirrors, a rear bumper, and a back door of the vehicle 300, and on an upper portion of a windshield in the interior of the vehicle.

The imaging unit 301 provided on the front nose mainly acquires an image of the front of the vehicle 300. The imaging unit 302 provided on the left side mirror and the imaging unit 303 provided on the right side mirror mainly acquire images of the sides of the vehicle 300. The imaging unit 304 provided to the rear bumper or the back door mainly acquires an image of the rear of the vehicle 300. The imaging unit 305 provided to the upper portion of the windshield in the interior of the vehicle mainly acquires an image of the front of the vehicle 300. The imaging unit 305 is used to detect, for example, a preceding vehicle, a pedestrian, an obstacle, a signal, a traffic sign, a lane, and the like.

FIG. 32 illustrates an example of imaging ranges of the imaging units 301, 302, 303, and 304 (hereinafter referred to as “imaging units 301 to 304”). An imaging range 311 represents the imaging range of the imaging unit 301 provided to the front nose. An imaging range 312 represents the imaging range of the imaging unit 302 provided to the left side mirror. An imaging range 313 represents the imaging range of the imaging unit 303 provided to the right side mirror. An imaging range 314 represents the imaging range of the imaging unit 304 provided to the rear bumper or the back door. For example, an overhead view of the vehicle 300 as viewed from above is obtained by superimposing image data captured by the imaging units 301 to 304. Hereinafter, the imaging ranges 311, 312, 313, and 314 are referred to as the “imaging ranges 311 to 314”.

At least one of the imaging units 301 to 304 may have a function of acquiring distance information. For example, at least one of the imaging units 301 to 304 may be a stereo camera including a plurality of imaging devices or an imaging device including pixels for phase difference detection.

For example, the microcomputer 251 (FIG. 31) calculates a distance to each three-dimensional object within the imaging ranges 311 to 314 and a temporal change in the distance (relative speed with respect to the vehicle 300) on the basis of the distance information obtained from the imaging units 301 to 304. On the basis of the calculation results, the microcomputer 251 can extract, as a preceding vehicle, a nearest three-dimensional object that is present on a traveling path of the vehicle 300 and travels in substantially the same direction as the vehicle 300 at a predetermined speed (for example, equal to or more than 0 km/h). Moreover, the microcomputer 251 can set a following distance to be maintained in front of a preceding vehicle in advance, and perform automatic brake control (including following stop control), automatic acceleration control (including following start control), or the like. According to this example, the cooperative control intended for automated driving that makes the vehicle travel autonomously and the like can be performed without depending on the operation of the driver.

For example, the microcomputer 251 can classify three-dimensional object data related to three-dimensional objects into a two-wheeled vehicle, a standard-sized vehicle, a large-sized vehicle, a pedestrian, a utility pole, and other three-dimensional objects on the basis of the distance information obtained from the imaging units 301 to 304, extract the classified three-dimensional object data, and use the extracted three-dimensional object data for automatic avoidance of an obstacle. For example, the microcomputer 251 identifies obstacles around the vehicle 300 as obstacles that the driver of the vehicle 300 can recognize visually and obstacles that are difficult for the driver of the vehicle 300 to recognize visually. Then, the microcomputer 251 determines a collision risk indicating a risk of collision with each obstacle, and in a situation in which the collision risk is equal to or higher than a set value and there is thus a possibility of collision, the microcomputer 251 can assist in driving to avoid collision by outputting a warning to the driver via the audio speaker 261 or the display unit 262, and performing forced deceleration or avoidance steering via the driving system control unit 210.

At least one of the imaging units 301 to 304 may be an infrared camera that detects infrared light. The microcomputer 251 can, for example, recognize a pedestrian by determining whether or not there is a pedestrian in images captured by the imaging units 301 to 304. Such recognition of a pedestrian is, for example, performed by a procedure of extracting characteristic points in the images captured by the imaging units 301 to 304 as infrared cameras and a procedure of determining whether or not an object is a pedestrian by performing pattern matching processing on a series of characteristic points representing the contour of the object. In a case where the microcomputer 251 determines that there is a pedestrian in the captured images captured by the imaging units 301 to 304 and recognizes the pedestrian, the sound/image output unit 252 controls the display unit 262 so that a square contour line for emphasis is displayed in a superimposed manner on the recognized pedestrian. Furthermore, the sound/image output unit 252 may also control the display unit 262 so that an icon or the like representing the pedestrian is displayed at a desired position.

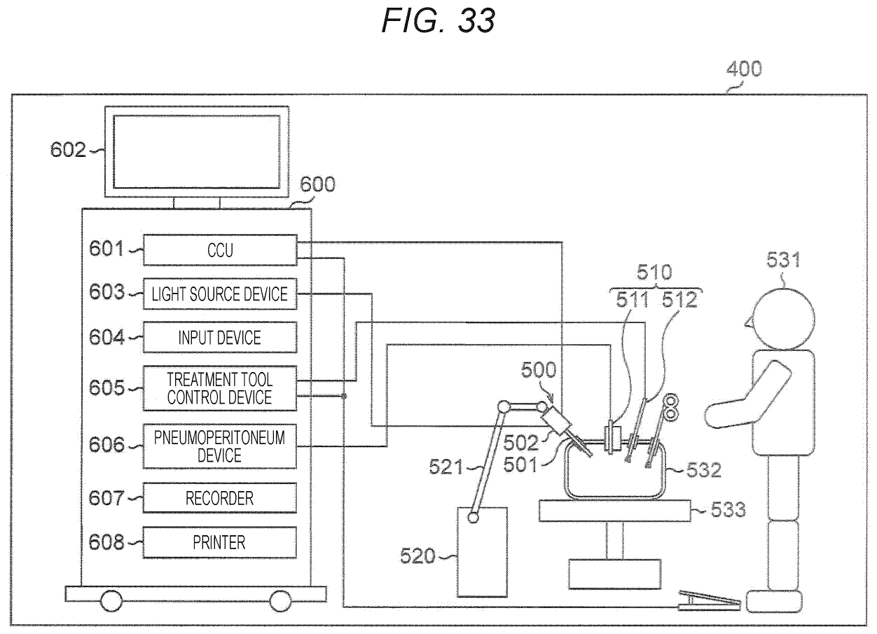

FIG. 33 is a diagram illustrating an example of a schematic configuration of an endoscopic surgery system to which the technology according to an embodiment of the present disclosure (present technology) can be applied.

In FIG. 33, a state is depicted in which a surgeon (medical doctor) 531 is using an endoscopic surgery system 400 to perform surgery for a patient 532 on a patient bed 533. As illustrated, the endoscopic surgery system 400 includes an endoscope 500, other surgical tools 510 such as a pneumoperitoneum tube 511 and an energy treatment tool 512, a supporting arm device 520 for supporting the endoscope 500, and a cart 600 on which various devices for endoscopic surgery are mounted.

The endoscope 500 includes a lens barrel 501 having a region of a predetermined length from a distal end thereof to be inserted into a body cavity of the patient 532, and a camera head 502 connected to a proximal end of the lens barrel 501. Although the illustrated example illustrates the endoscope 500 is configured as a so-called rigid endoscope having a rigid lens barrel 501, the endoscope 500 may be a so-called flexible endoscope having a flexible lens barrel.

An opening in which an objective lens is fitted is provided at the distal end of the lens barrel 501. A light source device 603 is connected to the endoscope 500, and light generated by the light source device 603 is guided to the distal end of the lens barrel by a light guide extending in the lens barrel 501 and is emitted to an observation target in the body cavity of the patient 532 through the objective lens. Note that the endoscope 500 may be a forward-viewing endoscope, an oblique-viewing endoscope, or a side-viewing endoscope.

An optical system and an imaging element are provided in the camera head 502, and light reflected by the observation target (observation light) is collected on the imaging element by the optical system. The imaging element photoelectrically converts the observation light and generates an electric signal corresponding to the observation light, that is, an image signal corresponding to an observation image. The image signal is transmitted to a camera control unit (CCU) 601 as RAW data.

The CCU 601 includes a central processing unit (CPU), a graphics processing unit (GPU), and the like, and integrally controls the operations of the endoscope 500 and a display device 602. Moreover, the CCU 601 receives the image signal from the camera head 502 and applies, on the image signal, various types of image processing, for example, development processing (demosaicing processing) or the like for displaying an image based on the image signal.

The display device 602 displays the image based on the image signal which has been subjected to the image processing by the CCU 601 under the control of the CCU 601.

The light source device 603 includes, for example, a light source such as a light emitting diode (LED), and supplies irradiation light for imaging a surgical site or the like to the endoscope 500.

An input device 604 is an input interface for the endoscopic surgery system 11000. A user can input various types of information and instructions to the endoscopic surgery system 400 via the input device 604. For example, the user inputs an instruction and the like to change an imaging condition (type of irradiation light, magnification, focal length and the like) by the endoscope 500.

A treatment tool control device 605 controls driving of the energy treatment tool 512 for tissue cauterization, incision, blood vessel sealing, and the like. A pneumoperitoneum device 606 sends gas into the body cavity of the patient 532 via the pneumoperitoneum tube 511 in order to inflate the body cavity for a purpose of securing a field of view by the endoscope 500 and securing work space for the operator. A recorder 607 is a device that can record various types of information regarding surgery. A printer 608 is a device that can print various types of information regarding surgery in various formats such as a text, an image, or a graph.

Note that the light source device 603 which supplies the irradiation light for imaging the surgical site to the endoscope 500 may include, for example, an LED, a laser light source, or a white light source obtained by combining these. In a case where the white light source includes a combination of RGB laser light sources, because an output intensity and an output timing of each color (each wavelength) can be controlled with high accuracy, the light source device 603 can adjust white balance of a captured image. Furthermore, in this case, by irradiating the observation target with the laser light from each of the R, G, and B laser light sources in time division and controlling driving of the imaging element of the camera head 502 in synchronism with the irradiation timing, images corresponding to R, G, and B can be captured in time division. With this method, a color image can be obtained even if color filters are not provided to the imaging element.

Furthermore, the driving of the light source device 603 may be controlled so that the intensity of light to be output is changed every predetermined time. The driving of the imaging element of the camera head 502 is controlled in synchronization with a timing of changing the light intensity to obtain the images in time division, and the obtained images are synthesized to enable generation of an image with a high dynamic range that does not have so-called black defect and halation.

Furthermore, the light source device 603 may be able to supply light in a predetermined wavelength band adapted to special light observation. In the special light observation, for example, by emitting light in a narrower band than irradiation light (in other words, white light) at the time of normal observation using wavelength dependency of a body tissue to absorb light, so-called narrow band imaging is performed in which an image of a predetermined tissue, such as a blood vessel in a mucosal surface layer, is captured with high contrast. Alternatively, in the special light observation, fluorescent observation for obtaining an image from fluorescent light generated by irradiation of excitation light may be performed. In the fluorescence observation, a body tissue can be irradiated with excitation light to observe fluorescence from the body tissue (autofluorescence observation) or a reagent such as indocyanine green (ICG) is locally injected to a body tissue and irradiate the body tissue with excitation light corresponding to a fluorescent wavelength of the reagent to obtain a fluorescent image. The light source device 603 can be configured to supply narrow band light and/or excitation light adapted to such special light observation.

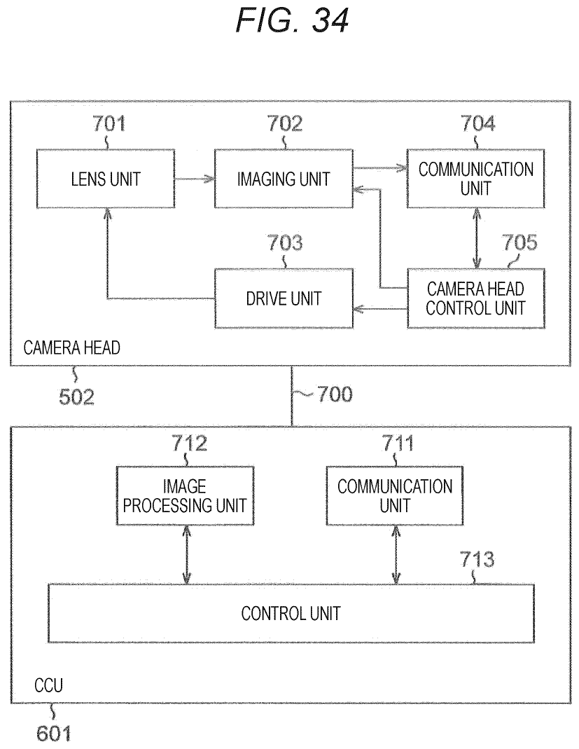

FIG. 34 is a block diagram illustrating an example of a functional configuration of the camera head 502 and the CCU 601 illustrated in FIG. 33.

The camera head 502 includes a lens unit 701, an imaging unit 702, a drive unit 703, a communication unit 704, and a camera head control unit 705. The CCU 601 includes a communication unit 711, an image processing unit 712, and a control unit 713. The camera head 502 and the CCU 601 are connected to each other communicably by a transmission cable 700.

The lens unit 701 is an optical system provided at a connection portion with the lens barrel 501. The observation light captured from the distal end of the lens barrel 501 is guided to the camera head 502 and enters the lens unit 701. The lens unit 701 is configured by combining a plurality of lenses including a zoom lens and a focus lens.

The imaging unit 702 includes an imaging element. The number of imaging elements included in the imaging unit 702 may be one (so-called single plate type) or two or more (so-called multiple plate type). In a case where the imaging unit 702 is configured as the multiple plate type, for example, image signals corresponding to R, G, and B may be generated by the respective imaging elements, and a color image may be obtained by combining the generated image signals. Alternatively, the imaging unit 702 may include a pair of imaging elements for obtaining right-eye and left-eye image signals corresponding to three-dimensional (3D) display. By performing the 3D display, the surgeon 531 can grasp a depth of a living body tissue in a surgical site more accurately. Note that, in a case where the imaging unit 702 is configured as the multiple plate type, a plurality of systems of lens units 701 may be provided so as to correspond to the respective imaging elements. The imaging unit 702 is, for example, the solid-state imaging device according to any of the first to seventh embodiments.

Furthermore, the imaging unit 702 is not necessarily provided in the camera head 502. For example, the imaging unit 702 may be provided inside the lens barrel 501 immediately behind the objective lens.

The drive unit 703 includes an actuator and moves the zoom lens and the focusing lens of the lens unit 701 by a predetermined distance along an optical axis under the control of the camera head control unit 705. With this arrangement, the magnification and focal point of the image captured by the imaging unit 702 may be appropriately adjusted.

The communication unit 704 includes a communication device for transmitting and receiving various types of information to and from the CCU 601. The communication unit 704 transmits the image signal obtained from the imaging unit 702 as the RAW data to the CCU 601 via the transmission cable 700.

Furthermore, the communication unit 704 receives a control signal for controlling driving of the camera head 502 from the CCU 601 and supplies the control signal to the camera head control unit 705. The control signal includes, for example, the information regarding the imaging condition such as information specifying a frame rate of the captured image, information specifying an exposure value at the time of imaging, and/or information specifying the magnification and focus of the captured image.

Note that the imaging conditions such as the frame rate, exposure value, magnification, and focus described above may be appropriately specified by the user, or may be automatically set by the control unit 713 of the CCU 601 on the basis of the acquired image signal. In the latter case, the endoscope 500 is equipped with a so-called auto exposure (AE) function, an auto focus (AF) function, and an auto white balance (AWB) function.

The camera head control unit 705 controls the driving of the camera head 502 on the basis of the control signal from the CCU 601 received via the communication unit 704.

The communication unit 711 includes a communication device for transmitting and receiving various types of information to and from the camera head 502. The communication unit 711 receives the image signal transmitted from the camera head 502 via the transmission cable 700.

Furthermore, the communication unit 711 transmits the control signal for controlling the driving of the camera head 502 to the camera head 502. The image signal and the control signal can be transmitted by electrical communication, optical communication or the like.

The image processing unit 712 performs various types of image processing on the image signal which is the RAW data transmitted from the camera head 502.

The control unit 713 performs various types of control regarding imaging of the surgical site and the like by the endoscope 500 and display of the captured image obtained by the imaging of the surgical site and the like. For example, the control unit 713 generates the control signal for controlling the driving of the camera head 502.

Furthermore, the control unit 713 allows the display device 602 to display the captured image including the surgical site and the like on the basis of the image signal subjected to the image processing by the image processing unit 712. At this time, the control unit 713 may recognize various objects in the captured image using various image recognition technologies. For example, the control unit 713 can detect edge shapes, colors, and the like of the objects included in the captured image, to recognize the surgical tool such as forceps, a specific living body site, bleeding, mist when the energy treatment tool 512 is used, and the like. At the time of causing the display device 602 to display the captured image, the control unit 713 may overlay various types of surgery assistance information on the image of the surgical site using the recognition result. The surgery assistance information is displayed to be overlaid and presented to the surgeon 531, which can reduce the burden on the surgeon 531 and enable the surgeon 531 to reliably proceed with surgery.

The transmission cable 700 connecting the camera head 502 and the CCU 601 is an electric signal cable compatible with communication of electric signals, an optical fiber compatible with optical communication, or a composite cable thereof. Here, in the illustrated example, the communication is performed wired using the transmission cable 700, but the communication between the camera head 502 and the CCU 601 may be performed wirelessly.

Although the embodiments of the present disclosure have been described above, these embodiments may be implemented with various modifications within a scope not departing from the gist of the present disclosure. For example, two or more embodiments may be implemented in combination.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.

(1)

A light receiving device including:
a substrate including a photodetector;
an optical system provided above the photodetector; and
a first light shielding layer provided between the photodetector and the optical system and having a first opening, in which
the optical system includes a microlens having a shape concave toward a side of a subject.
   (2)

The light receiving device according to (1), in which the optical system further includes a microlens having a shape convex toward the side of the subject.

(3)

The light receiving device according to (2), in which
the optical system includes, as the microlens,
a first lens having a shape convex toward the side of the subject,
a second lens provided above the first lens and having a shape convex toward the side of the subject, and
a third lens provided above the second lens and having a shape concave toward the side of the subject.
   (4)

The light receiving device according to (3), in which
an optical axis of the second lens is on a first direction side with respect to an optical axis of the first lens, and
an optical axis of the third lens is on a side opposite to the first direction with respect to an optical axis of the first lens.
   (5)

The light receiving device according to (3), in which the first opening is provided at a position not overlapping with an optical axis of the first lens.

(6)

The light receiving device according to (1), further including a first transparent layer provided between the substrate and the first light shielding layer.

(7)

The light receiving device according to (1), further including a second light shielding layer provided between the photodetector and the first light shielding layer and having a second opening.

(8)

The light receiving device according to (7), in which the second opening is provided at a position not overlapping with the first opening in plan view.

(9)

The light receiving device according to (7), further including a second transparent layer provided between the substrate and the second light shielding layer.

(10)

The light receiving device according to (1), further including, as the photodetector and the optical system, a plurality of photodetectors provided in the substrate, and a plurality of optical systems provided above the plurality of photodetectors.

(11)

The light receiving device according to (10), further including a common lens provided above the plurality of optical systems.

(12)

The light receiving device according to (11), in which one of an upper surface and a lower surface of the common lens has a convex or concave shape toward the side of the subject.

(13)

The light receiving device according to (12), in which another of the upper surface and the lower surface of the common lens is a flat surface.

(14)

The light receiving device according to (12), in which another of the upper surface and the lower surface of the common lens also has a convex or concave shape toward the side of the subject.

(15)

The light receiving device according to (11), in which the common lens functions as a Fresnel lens or a hologram element.

(16)

The light receiving device according to (1), further including a transparent member provided above the optical system.

(17)

The light receiving device according to (1), in which at least one of an angle θ between an upper light beam and a lower light beam in the optical system, a focal length f of the optical system, or a diameter d of the first opening has a value satisfying −10°≤θ≤10°, 0.0003 mm<f<3 mm, or 0.02 μm<d <3 μm.

(18)

An electronic device including:
a substrate including a photodetector;
an optical system provided above the photodetector; and
a first light shielding layer provided between the photodetector and the optical system and having a first opening, in which
the optical system includes a microlens having a shape concave toward a side of a subject.
   (19)

The electronic device according to (18), in which the electronic device functions as an imaging device that images the subject.

(20)

The electronic device according to (19), in which the electronic device further functions as an authentication device that authenticates the subject using an image obtained by imaging the subject.

### REFERENCE SIGNS LIST

1 Pixel
2 Pixel array region
3 Control circuit
4 Vertical drive circuit
5 Column signal processing circuit
6 Horizontal drive circuit
7 Output circuit
8 Vertical signal line
9 Horizontal signal line
11 Substrate
12 Transparent layer
13 Light shielding layer
13a Pinhole
14 Optical system
14a Lower lens
14b Intermediate lens
14c Upper lens
15 Transparent layer
16 Light shielding layer
16a Pinhole
21 Lens array
22 Common lens
23 Support substrate
24 Imaging assembly
31 Glass cover
32 PC
33 Display
41 Glass cover
42 PC
43 Display
50 Upper substrate
51 Substrate
51a Well region
51b Source/drain region
51c n-type semiconductor region
51d p-type semiconductor region
52 Gate electrode
53 Element isolation insulating film
54 Interlayer insulating film
55 Contact plug
56 Wiring layer
57 Multilayer wiring structure
60 Lower substrate
61 Substrate
61a Well region
61b Source/drain region
62 Gate electrode
63 Element isolation insulating film
64 Interlayer insulating film
65 Contact plug
66 Wiring layer
67 Multilayer wiring structure
68 Warp correction film
71 Antireflection film
72 Insulating film
72a Light shielding groove
73 Light shielding layer
74 Planarization film
75 Color filter
76 Lens material
77 Planarization film
78 Planarization film
79 Lens material
79a Concave portion
81 Control circuit
82 Logic circuit

1. A light receiving device comprising:
a substrate including a photodetector;
an optical system provided above the photodetector; and
a first light shielding layer provided between the photodetector and the optical system and having a first opening, wherein
the optical system includes a microlens having a shape concave toward a side of a subject.

2. The light receiving device according to claim 1, wherein the optical system further includes a microlens having a shape convex toward the side of the subject.

3. The light receiving device according to claim 2, wherein
the optical system includes, as the microlens,
a first lens having a shape convex toward the side of the subject,
a second lens provided above the first lens and having a shape convex toward the side of the subject, and
a third lens provided above the second lens and having a shape concave toward the side of the subject.

4. The light receiving device according to claim 3, wherein
an optical axis of the second lens is on a first direction side with respect to an optical axis of the first lens, and
an optical axis of the third lens is on a side opposite to the first direction with respect to an optical axis of the first lens.

5. The light receiving device according to claim 3, wherein the first opening is provided at a position not overlapping with an optical axis of the first lens.

6. The light receiving device according to claim 1, further comprising a first transparent layer provided between the substrate and the first light shielding layer.

7. The light receiving device according to claim 1, further comprising a second light shielding layer provided between the photodetector and the first light shielding layer and having a second opening.

8. The light receiving device according to claim 7, wherein the second opening is provided at a position not overlapping with the first opening in plan view.

9. The light receiving device according to claim 7, further comprising a second transparent layer provided between the substrate and the second light shielding layer.

10. The light receiving device according to claim 1, further comprising, as the photodetector and the optical system, a plurality of photodetectors provided in the substrate, and a plurality of optical systems provided above the plurality of photodetectors.

11. The light receiving device according to claim 10, further comprising a common lens provided above the plurality of optical systems.

12. The light receiving device according to claim 11, wherein one of an upper surface and a lower surface of the common lens has a convex or concave shape toward the side of the subject.

13. The light receiving device according to claim 12, wherein another of the upper surface and the lower surface of the common lens is a flat surface.

14. The light receiving device according to claim 12, wherein another of the upper surface and the lower surface of the common lens also has a convex or concave shape toward the side of the subject.

15. The light receiving device according to claim 11, wherein the common lens functions as a Fresnel lens or a hologram element.

16. The light receiving device according to claim 1, further comprising a transparent member provided above the optical system.

17. The light receiving device according to claim 1, wherein at least one of an angle θ between an upper light beam and a lower light beam in the optical system, a focal length f of the optical system, or a diameter d of the first opening has a value satisfying −10°≤θ≤10°, 0.0003 mm<f<3 mm, or 0.02 μm<d<3 μm.

18. An electronic device comprising:
a substrate including a photodetector;
an optical system provided above the photodetector; and
a first light shielding layer provided between the photodetector and the optical system and having a first opening, wherein
the optical system includes a microlens having a shape concave toward a side of a subject.

19. The electronic device according to claim 18, wherein the electronic device functions as an imaging device that images the subject.

20. The electronic device according to claim 19, wherein the electronic device further functions as an authentication device that authenticates the subject using an image obtained by imaging the subject.
